(19) United States
(12) Patent Application Publication
(10) Pub. No.: US 2023/0194990 A1
(43) Pub. Date: Jun. 22, 2023

(54) PHOTORESIST UNDERLAYER COMPOSITION

(71) Applicant: Rohm and Haas Electronic Materials LLC, Marlborough, MA (US)

(72) Inventors: Iou-Sheng KE, Andover, MA (US); Anton CHAVEZ, West Newton, MA (US); Shintaro YAMADA, Shrewsbury, MA (US)

(21) Appl. No.: 18/076,475

(22) Filed: Dec. 7, 2022

Related U.S. Application Data
(60) Provisional application No. 63/292,138, filed on Dec. 21, 2021.

(51) Int. Cl. G03F 7/11; C09D 165/02; H01L 21/027

(52) U.S. Cl. CPC G03F 7/11; C09D 165/02; H01L 21/0274

(57) ABSTRACT

A method of forming a pattern, the method comprising: applying a photoresist underlayer composition over a substrate to provide a photoresist underlayer; forming a photoresist layer over the photoresist underlayer; patterning the photoresist layer; and transferring a pattern from the patterned photoresist layer to the photoresist underlayer. The photoresist underlayer composition includes a polymer that includes a repeating unit represented by Formula 1 as described herein, a compound including a substituent group represented by Formula 2 as described herein, and a solvent.

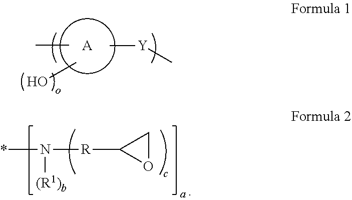

### CROSS-REFERENCE TO RELATED APPLICATIONS

This application claims the benefit of U.S. Provisional Application No. 63/292,138, filed Dec. 21, 2021, which is incorporated by reference herein in its entirety.

### FIELD

The present invention relates to a manufacturing of electronic devices, and more specifically, to materials for use in semiconductor manufacture.

### BACKGROUND

Photoresist underlayer compositions are used in the semiconductor industry as etch masks for lithography in advanced technology nodes for integrated circuit manufacturing. These compositions are often used in tri-layer and quad-layer photoresist integration schemes, where an organic or silicon containing anti-reflective coating and patternable photoresist film layers having a high carbon content are disposed on a bottom layer, e.g., a substrate.

Spin-on Carbon (SOC) compositions are used to form resist underlayer films in the semiconductor industry, which are used as etch masks for lithography in advanced technology nodes for integrated circuit manufacturing. These compositions are often used in tri-layer and quad-layer photoresist integration schemes, where an organic or silicon containing anti-reflective coating and a patternable photoresist film layers having a high carbon content SOC material are disposed on a bottom layer.

An ideal SOC material should possess certain specific characteristics: should be capable of being cast onto a substrate by a spin-coating process; should be thermally set upon heating with low out-gassing and sublimation; should be soluble in common solvents for good spin bowl compatibility; should have appropriate n/k to work in conjunction with the anti-reflective coating layer to impart low reflectivity necessary for photoresist imaging; should be sufficiently adhered to a lower layer, e.g., a substrate, to avoid delamination when submerged during a standard cleaning process, for example, a SC-1 process using a hydrogen peroxide/ammonium hydroxide bath; and should have high thermal stability to avoid damage during subsequent processing steps. In addition, a SOC material should possess material flow ability (referred to as planarization, PL) on complicated topography design in advanced node.

Accordingly, there remains a need for advanced SOC compositions and resulting photoresist underlayer films/materials that exhibit acceptable adhesion to an underlying layer/substrate and acceptable planarization to meet the ever increasing design requirements in semiconductor manufacturing.

### SUMMARY

Provided is a method of forming a pattern, the method comprising:
applying a photoresist underlayer composition over a substrate to provide a photoresist underlayer;
forming a photoresist layer over the photoresist underlayer;
patterning the photoresist layer; and
transferring a pattern from the patterned photoresist layer to the photoresist underlayer;
wherein the photoresist underlayer composition comprises a polymer that includes a repeating unit represented by Formula 1, a compound including a substituent group represented by Formula 2; and a solvent;

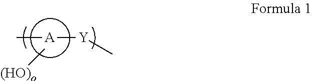

wherein in Formula 1

Ring A represents an aromatic ring group with one to six independently substituted or unsubstituted aromatic rings, wherein optionally, two or more of the aromatic rings are fused, one or more aromatic rings includes a fused optionally substituted cycloalkyl or an optionally substituted fused heterocycloalkyl, or a combination thereof,

Y is a divalent group comprising an optionally substituted C₁₋₄ alkylene, —O—, —S—, C(O)—, an optionally substituted arylene, or an optionally substituted heteroarylene, with one or two aromatic rings, or a combination thereof, and

o is an integer from 2 to 8;

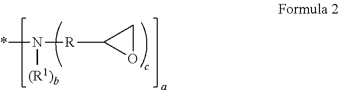

wherein, in Formula 2:

R is a substituted or unsubstituted C₁₋₄ alkylene, —CR^{A}R^{B}—Ar—CH₂—, or —Ar—CH₂—, where Ar is an optionally substituted arylene or heteroarylene with 4 to 10 ring carbons, and R^{A} and R^{B} are independently hydrogen, hydroxy, optionally substituted C₁₋₆ alkyl, optionally substituted C₁₋₆ alkoxy, or optionally substituted C₆₋₁₂ aryl;

R¹ is hydrogen, an optionally substituted C₁₋₄ alkyl, an optionally substituted C₆₋₁₂ aryl, an optionally substituted C₃₋₈ cycloalkyl, or glycidyl;

* is a connection point to a ring carbon of aromatic ring system Q, wherein the aromatic ring system Q is Ar¹ or Ar²-T-Ar³,

wherein Ar¹, Ar², and Ar³ comprise independently a substituted or unsubstituted aromatic group with 4 to 14 ring carbons, and

T is absent, —O—, —S—, —C(O)—, an optionally substituted C₁₋₄ alkylene, or —NR²—, wherein R² is hydrogen, an optionally substituted C₁₋₄ alkyl, or an optionally substituted C₆₋₁₂ aryl; and

a is 1 to 8, c is 1, 2, or 3, and b+c is 2 or 3.

Also provided is the composition above, wherein the photoresist underlayer composition is free of non-polymeric polyphenol compounds and thermal base generators.

Also provided is a substrate including a layer of the above-described photoresist underlayer composition disposed on a substrate; and a photoresist layer disposed on the layer of the photoresist underlayer composition.

Also provided is a photoresist underlayer composition comprising a polymer that includes a repeating unit represented by Formula 1 as described herein, a compound including a substituent group represented by Formula 2 as described herein, and a solvent.

### DETAILED DESCRIPTION

Reference will now be made in detail to exemplary embodiments, examples of which are illustrated in the present description. In this regard, the present exemplary embodiments may have different forms and should not be construed as being limited to the descriptions set forth herein. Accordingly, the exemplary embodiments are merely described below, by referring to the figures, to explain aspects of the present description. As used herein, the term “and/or” includes all combinations of one or more of the associated listed items. Expressions such as “at least one of,” when preceding a list of elements, modify the entire list of elements and do not modify the individual elements of the list.

As used herein, the terms “a,” “an,” and “the” do not denote a limitation of quantity and are to be construed to cover both the singular and the plural, unless otherwise indicated herein or clearly contradicted by context. “Or” means “and/or” unless clearly indicated otherwise. All ranges disclosed herein are inclusive of the endpoints, and the endpoints are independently combinable with each other. The suffix “(s)” is intended to include both the singular and the plural of the term that it modifies, thereby including at least one of that term. “Optional” or “optionally” means that the subsequently described event or circumstance can or cannot occur, and that the description includes instances where the event occurs and instances where it does not. The terms “first,” “second,” and the like, herein do not denote an order, quantity, or importance, but rather are used to distinguish one element from another. When an element is referred to as being “on” another element, it may be directly in contact with the other element or intervening elements may be present therebetween. In contrast, when an element is referred to as being “directly on” another element, there are no intervening elements present. It is to be understood that the described components, elements, limitations, and/or features of aspects may be combined in any suitable manner in the various aspects.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, the term “hydrocarbon group” refers to an organic compound having at least one carbon atom and at least one hydrogen atom, optionally substituted with one or more substituents where indicated; “alkyl group” refers to a straight or branched chain saturated hydrocarbon having the specified number of carbon atoms and having a valence of one; “alkylene group” refers to an alkyl group having a valence of two; “hydroxyalkyl group” refers to an alkyl group substituted with at least one hydroxyl group (—OH); “alkoxy group” refers to “alkyl-O—”; “carboxylic acid group” refers to a group having the formula “—C(═O)—OH”; “cycloalkyl group” refers to a monovalent group having one or more saturated rings in which all ring members are carbon; “cycloalkylene group” refers to a cycloalkyl group having a valence of two; “alkenyl group” refers to a straight or branched chain, monovalent hydrocarbon group having at least one carbon-carbon double bond; “alkenoxy group” refers to “alkenyl-O—”; “alkenylene group” refers to an alkenyl group having a valence of at least two; “cycloalkenyl group” refers to a cycloalkyl group having at least one carbon-carbon double bond; “alkynyl group” refers to a monovalent hydrocarbon group having at least one carbon-carbon triple bond; the term “aromatic group” denotes the conventional idea of aromaticity as defined in the literature, in particular in IUPAC 19, and refers to a monocyclic or polycyclic aromatic ring system that includes carbon atoms in the ring or rings, and optionally may include one or more heteroatoms independently selected from N, O, and S instead of a carbon atom or carbon atoms in the ring or rings; “aryl group” refers to a monovalent, monocyclic or polycyclic aromatic group containing only carbon atoms in the aromatic ring or rings, and may include a group with an aromatic ring fused to at least one cycloalkyl or heterocycloalkyl ring; “arylene group” refers to an aryl group having a valence of at least two; “alkylaryl group” refers to an aryl group that has been substituted with an alkyl group; “arylalkyl group” refers to an alkyl group that has been substituted with an aryl group; “aryloxy group” refers to “aryl-O—”; and “arylthio group” refers to “aryl-S—”.

The prefix “hetero” means that the compound or group includes at least one member that is a heteroatom (e.g., 1, 2, 3, or 4 or more heteroatom(s)) instead of a carbon atom, wherein the heteroatom(s) is each independently selected from N, O, S, Si, or P; “heteroatom-containing group” refers to a substituent group that includes at least one heteroatom; “heteroalkyl group” refers to an alkyl group having 1-4 heteroatoms instead of carbon atoms; “heterocycloalkyl group” refers to a cycloalkyl group with one or more N, O or S atoms instead of carbon atoms; “heterocycloalkylene group” refers to a heterocycloalkyl group having a valence of at least two; “heteroaryl group” refers to an aryl group having 1 to 3 separate or fused rings with one or more N, O or S atoms as ring members instead of carbon atoms; and “heteroarylene group” refers to a heteroaryl group having a valence of at least two.

The symbol “*” represents a bonding site (i.e., point of attachment).

“Substituted” or “substituent group” means that at least one hydrogen atom on the group is replaced with another group, provided that the designated atom's normal valence is not exceeded. When the substituent is oxo (i.e., ═O), then two hydrogens on the carbon atom are replaced. Combinations of two or more substituents or variables are permissible. For example, the term “substituted” may refer to the stated hydrocarbon moiety with two, three, or four of the same or different substituent groups. Exemplary groups that may be present on a “substituted” position include, but are not limited to, nitro (—NO₂), cyano (—CN), hydroxyl (—OH), oxo (═O), amino (—NH₂), mono- or di-(C₁₋₆)alkylamino, alkanoyl (such as a C₂₋₆ alkanoyl group such as acyl), formyl (—C(═O)H), carboxylic acid or an alkali metal or ammonium salt thereof, C₂₋₆ alkyl ester (—C(═O)O-alkyl or —OC(═O)-alkyl), C₇₋₁₃ aryl ester (—C(═O)O-aryl or —OC(═O)-aryl), amido (—C(═O)NR₂ wherein R is hydrogen or C₁₋₆ alkyl), carboxamido (—CH₂C(═O)NR₂ wherein R is hydrogen or C₁₋₆ alkyl), halogen, thiol (—SH), C₁₋₆ alkylthio (—S-alkyl), thiocyano (—SCN), C₁₋₆ alkyl, C₂₋₆ alkenyl, C₂₋₆ alkynyl, C₁₋₆ haloalkyl, C₁₋₉ alkoxy, C₁₋₆ haloalkoxy, C₃₋₁₂ cycloalkyl, C₅₋₁₈ cycloalkenyl, C₆₋₁₂ aryl having at least one aromatic ring (e.g., phenyl, biphenyl, naphthyl, or the like, each ring either substituted or unsubstituted aromatic), C₇₋₁₉ arylalkyl having 1 to 3 separate or fused rings and from 6 to 18 ring carbon atoms, arylalkoxy having 1 to 3 separate or fused rings and from 6 to 18 ring carbon atoms, C₇₋₁₂ alkylaryl, C₄₋₁₂ heterocycloalkyl, C₃₋₁₂ heteroaryl, C₁₋₆ alkyl sulfonyl (—S(═O)₂-alkyl), C₆₋₁₂ arylsulfonyl (—S(═O)₂-aryl), or tosyl (CH₃C₆H₄SO₂—). When a group is substituted, the indicated number of carbon atoms is the total number of carbon atoms in the group, excluding those of any substituents. For example, the group —CH₂CH₂CN is a C₂ alkyl group substituted with a cyano group.

As used herein, the terms “polymer” and “polymeric” refer to a polymeric material that includes one or more repeating units, where the repeating units may be the same or different from each other. Thus, the disclosed polymers and polymeric materials of the invention can be referred to herein as a “polymer” or a “copolymer.” It is to be further understand that the terms “polymer” and “polymeric” further include oligomers. As used herein, each of the one or more different repeating units are present in the polymeric material at least two times. In other words, a polymeric material including one repeating unit includes a first repeating unit that is present in an amount of two or more, and, for example, a polymeric material including two repeating units includes a first repeating unit that is present in an amount of two or more, and a second repeating unit that is present in an amount of two or more.

As used herein, when a definition is not otherwise provided, a “divalent linking group” refers to a divalent group including one or more of —O—, —S—, —Te—, —Se—, —C(O)—, —N(R^{a})—, —S(O)—, —S(O)₂—, —C(S)—, —C(Te)—, —C(Se)—, substituted or unsubstituted C₁₋₃₀ alkylene, substituted or unsubstituted C₃₋₃₀ cycloalkylene, substituted or unsubstituted C₁₋₃₀ heterocycloalkylene, substituted or unsubstituted C₆₋₃₀ arylene, substituted or unsubstituted C₇₋₃₀ arylalkylene, substituted or unsubstituted C₁₋₃₀ heteroarylene, substituted or unsubstituted C₃₋₃₀ heteroarylalkylene, or a combination thereof, wherein R^{a} is hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₄₋₃₀ heteroaryl. More typically, the divalent linking group includes one or more of —O—, —S—, —C(O)—, —S(O)—, —S(O)₂—, substituted or unsubstituted C₁₋₃₀ alkylene, substituted or unsubstituted C₃₋₃₀ cycloalkylene, substituted or unsubstituted C₁₋₃₀ heterocycloalkylene, substituted or unsubstituted C₆₋₃₀ arylene, substituted or unsubstituted C₇₋₃₀ arylalkylene, substituted or unsubstituted C₁₋₃₀ heteroarylene, substituted or unsubstituted C₃₋₃₀ heteroarylalkylene, or a combination thereof, wherein R′ is hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₄₋₃₀ heteroaryl.

Organic underlayer films may be used to protect underlying substrates during various pattern transfer and etch processes. Often these films are cast and cured directly upon an inorganic substrate (e.g., TiN). In these cases, it is desirable that the underlayer film has sufficient adhesion to the substrate during all subsequent processing steps to protect the substrate from otherwise damaging processing conditions. One commonly used processing step is the wet etch process known as SC-1, which involves submerging the substrate and underlayers into a hydrogen peroxide/ammonium hydroxide bath. An underlayer film that is not sufficiently adhered to the substrate may delaminate while it is submerged, resulting in exposure of and damage to the underlying inorganic substrate. See, SC1 Resistance Evaluation, infra.

It is also desirable that the underlayer film has sufficient planarization properties to provide the film with a relatively flat top surface if the underlying layer or substrate includes various pitch, various line/space patterns, and/or various trench depths. See, PL Evaluation, infra.

In an embodiment, we provide a composition that may be applied to an underlayer or substrate to form a film layer over a substrate, that is, as a photoresist underlayer. In one aspect, the photoresist underlayer composition comprises a polymer that includes a repeating unit represented by Formula 1, for example, a repeating unit of Formula 1A or Formula 1B, a compound comprising a substituent group represented by Formula 2, and a solvent, infra.

In an embodiment, we provide a method of forming a pattern, the method comprising:
applying a photoresist underlayer composition over a substrate to provide a photoresist underlayer;
forming a photoresist layer over the photoresist underlayer;
patterning the photoresist layer; and
transferring a pattern from the patterned photoresist layer to the photoresist underlayer;
wherein the photoresist underlayer composition comprises a polymer that includes a repeating unit represented by Formula 1, a compound including a substituent group represented by Formula 2; and a solvent;

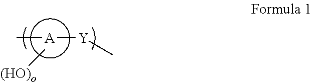

wherein in Formula 1

Ring A represents an aromatic ring group with one to six independently substituted or unsubstituted aromatic rings, wherein optionally, two or more of the aromatic rings are fused, one or more aromatic rings includes a fused optionally substituted cycloalkyl or an optionally substituted fused heterocycloalkyl, or a combination thereof,

Y is a divalent group comprising an optionally substituted C₁₋₄ alkylene, —O—, —S—, C(O)—, an optionally substituted arylene, or an optionally substituted heteroarylene, with one or two aromatic rings, or a combination thereof, and

o is an integer from 2 to 8;

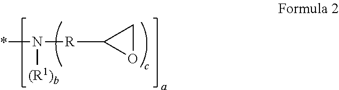

wherein, in Formula 2:

R is a substituted or unsubstituted C₁₋₄ alkylene, —CR^{A}R^{B}—Ar—CH₂—, or —Ar—CH₂—, where Ar is an optionally substituted arylene or heteroarylene with 4 to 10 ring carbons, and R^{A} and R^{B} are independently hydrogen, hydroxy, optionally substituted C₁₋₆ alkyl, optionally substituted C₁₋₆ alkoxy, or optionally substituted C₆₋₁₂ aryl;

R¹ is hydrogen, an optionally substituted C₁₋₄ alkyl, an optionally substituted C₆₋₁₂ aryl, an optionally substituted C₃₋₈ cycloalkyl, or glycidyl;

* is a connection point to a ring carbon of aromatic ring system Q, wherein the aromatic ring system Q is Ar¹ or Ar²-T-Ar³,

wherein Ar¹, Ar², and Ar³ comprise independently a substituted or unsubstituted aromatic group with 4 to 14 ring carbons, and

T is absent, —O—, —S—, —C(O)—, an optionally substituted C₁₋₄ alkylene, or —NR²—, wherein R² is hydrogen, an optionally substituted C₁₋₄ alkyl, or an optionally substituted C₆₋₁₂ aryl; and

a is 1 to 8, c is 1, 2, or 3, and b+c is 2 or 3.

Ring A represents an aromatic group with one to four independently substituted or unsubstituted aromatic rings, where o is an integer from 2 to 8, preferably, an integer from 2 to 4. If Ring A includes two or more aromatic rings, the two or more of aromatic rings can be connected by a single bond or a divalent linker, or two or more of the aromatic rings can be fused aromatic rings. Alternatively, two or more of the aromatic rings of Ring A can be connected by a divalent group and the remaining aromatic rings can be fused aromatic rings. In one aspect, the divalent linker can include a single bond, an optionally substituted C₁₋₄ alkylene, —O—, or —C(O)—. As indicated above, Ring A may be monocyclic or polycyclic. When the group is polycyclic, the ring or ring groups can be fused (such as naphthyl, anthracenyl, pyrenyl, or the like), directly linked (such as biphenyl, or the like), bridged by a heteroatom (such as triphenylamino or diphenylene ether). In an embodiment, the polycyclic aromatic group may include a combination of fused and directly linked rings (such as a linking of two naphthylene or the like).

In one aspect, Ring A may be an aromatic group with five to twenty ring carbons, or five to fourteen ring carbons, and optionally, include one to four ring heteroatoms chosen from N, O, or S.

Ring A includes two to eight hydroxy groups. It is further understood that any one or more ring carbons of Ring A may be substituted as described herein. For example, one to ten ring carbons of Ring A may be substituted.

In one aspect, a list of exemplary substituents may include, but is not limited to, substituted or unsubstituted C₁₋₁₈ alkyl, substituted or unsubstituted C₁₋₁₈ alkoxy, substituted or unsubstituted C₁₋₁₈ haloalkyl, substituted or unsubstituted C₃₋₈ cycloalkyl, substituted or unsubstituted C₁₋₈ heterocycloalkyl, substituted or unsubstituted C₂₋₁₈ alkenyl, substituted or unsubstituted C₂₋₁₈ alkynyl, substituted or unsubstituted C₆₋₁₄ aryl, substituted or unsubstituted C₆₋₁₈ aryloxy, substituted or unsubstituted C₇₋₁₄ arylalkyl, substituted or unsubstituted C₇₋₁₄ alkylaryl, substituted or unsubstituted C₃₋₁₄ heteroaryl, halogen, —CN, —NO₂, —CO₂R⁴, where R⁴ is H, —OH, or C₁₋₆ alkyl.

In one aspect, Ring A may be represented by Formula 1A or Formula 1B:

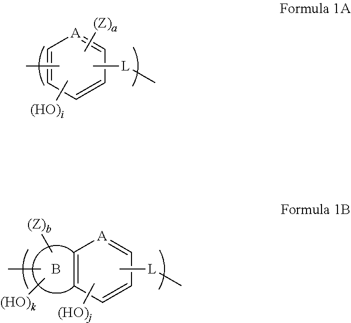

wherein, in Formula 1A and Formula 1B:

A is CR^{C} or N, wherein R^{C} is hydrogen, hydroxy, optionally substituted C₁₋₆ alkyl, optionally substituted C₁₋₆ alkoxy, or optionally substituted C₆₋₁₂ aryl;

ring B represents a fused aromatic group with one to four aromatic rings;

L is divalent group that comprises independently one to three optionally substituted C₁₋₄ alkylene, one to three —O—, optionally substituted arylene with one or two aromatic rings, or a combination thereof;

each Z is independently a substituent group where a of Formula 1A is 0 or 1, and b of Formula 1B is an integer from 0 to 10;

i is 2 or 3; j is 0, 1, or 2; and k is an integer from 0 to 6, wherein j+k is 2 or more.

The compound including a substituent group represented by Formula 2 includes an aromatic ring system Q, and Q is Ar¹ or Ar²-T-Ar³, where T is defined as in Formula 2 above. In one aspect, T is absent, —O—, or an optionally substituted —CH₂—.

In one aspect, Ar¹, Ar², and Ar³ are independently a substituted or unsubstituted phenyl, a substituted or unsubstituted naphthyl, a substituted or unsubstituted anthracenyl, a substituted or unsubstituted pyrenyl, a substituted or unsubstituted pyridinyl, a substituted or unsubstituted quinolinyl, a substituted or unsubstituted biphenylene, a substituted or unsubstituted triphenylene, a substituted or unsubstituted fluorenyl, or a substituted or unsubstituted carbazoyl, and each of which is optionally substituted with glycidyl.

In one aspect the compound comprising a substituent group represented by Formula 2 is represented by one of the following compounds

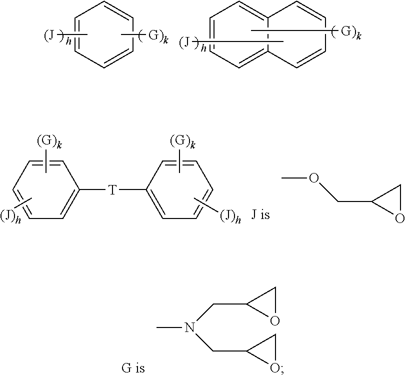

wherein k is 1, 2, 3, or 4, and each his 0, 1, or 2; and T is absent, O, S, —C(O)—, an optionally substituted C₁₋₄ alkylene, or —NR²—, wherein R² is H, an optionally substituted C₁₋₄ alkyl, or an optionally substituted C₆₋₁₀ aryl.

In one aspect, the compound comprising a substituent group represented by Formula 2 is represented as follows:
Q is Ar¹, and Ar¹ is phenyl, R is CH₂, a is 1 or 2, and c is 2;
Q is Ar¹, and Ar¹ is phenyl substituted with glycidyl, R is CH₂, a is 1 or 2, and c is 2;
Q is Ar²-T-Ar³, and Ar² and Ar³ are phenyl, and T is a absent, —O—, —C(O)—, or —CR^{B}R^{C}—, and for each of Ar² and Ar³, a is 1 or 2, and c is 2; or
Q is Ar²-T-Ar³, and Ar² or Ar³ is a phenyl substituted with glycidyl, and T is absent, —O—, —C(O)—, or —CR^{D}R^{E}—, and for each of Ar² and Ar³, a is 1 or 2, and c is 2,
wherein R^{D} and R^{E} are independently hydrogen, an optionally substituted C₁₋₄ alkyl, or an optionally substituted phenyl.

In one aspect the compound comprising a substituent group represented by Formula 2 is represented by one of the following compounds, wherein T is absent, O, S, —C(O)—, an optionally substituted C₁₋₄ alkylene, or —NR²—, wherein R² is H, an optionally substituted C₁₋₄ alkyl, or an optionally substituted C₆₋₁₀ aryl.

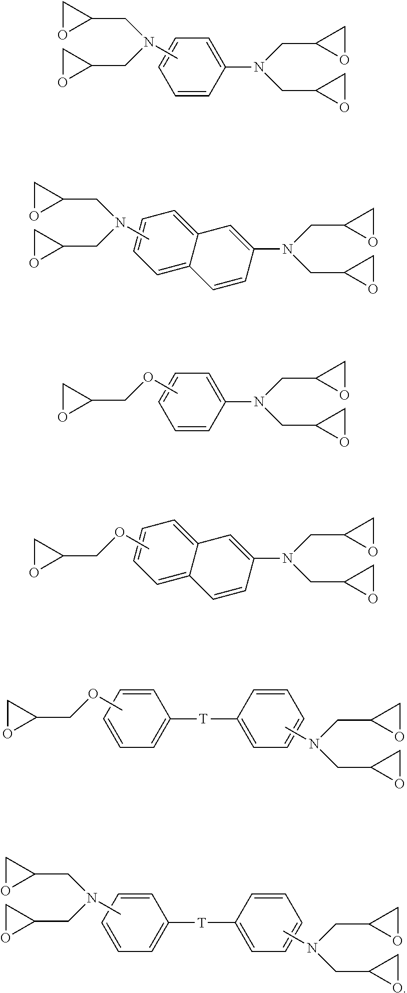

In one aspect, the repeating unit of Formula 1 is represented by at least one of the following:

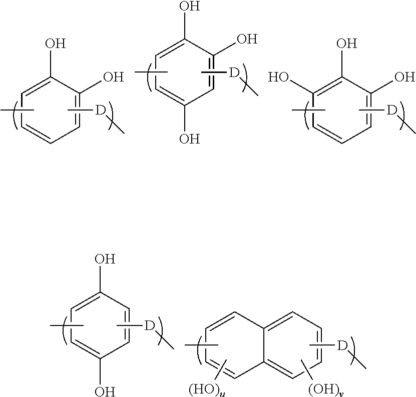

wherein

D is —CR^{D}R^{E}—, where R^{D} and R^{E} are independently hydrogen, an optionally substituted C₁₋₁₈ alkyl, an optionally C₆₋₂₂ aryl, or an optionally C₃₋₂₂ heteroaryl, and u is an integer of 0 to 3, v is an integer of 0 to 3, where u+v=2 or more.

In one aspect, the repeating unit of Formula 1 is represented by Formula 3A or Formula 3B;

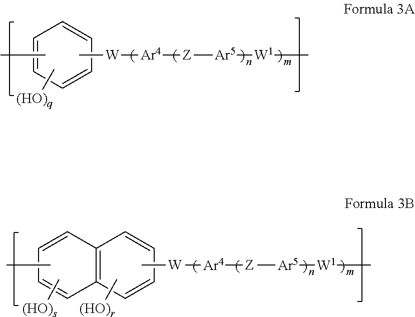

wherein, in Formulae 3A and 3B:

W and W¹ are independently an optionally substituted C₁₋₄ alkylene, —O—, or a combination thereof;

Ar⁴ and Ar⁵ are independently an optionally substituted C₆₋₁₄ arylene, or an optionally substituted C₃₋₁₄ heteroarylene;

Z is absent, O, —S—, —C(O)—, an optionally substituted C₁₋₄ alkylene;

m is 0, 1, or 2; n is 0 or 1; q is 2 or 3; and r and s are independently 0, 1, or 2, wherein r+s is 2 or more.

In one aspect, the repeating unit of Formula 3A or Formula 3B, if n is 0, and m is 1 or 2, then W and W¹ are independently —CR^{F}R^{G}—, and Ar⁴ is a substituted or unsubstituted phenyl, a substituted or unsubstituted pyridinyl, a substituted or unsubstituted biphenyl, or a substituted or unsubstituted naphthyl, wherein R^{F} and R^{G} are independently hydrogen, hydroxy, an optionally substituted C₁₋₁₈ alkyl, an optionally substituted C₁₋₁₈ alkoxy, Ar⁶, —CH₂Ar⁶, —OAr⁶, —Ar⁶R⁴, where Ar⁶ is an optionally substituted C₆₋₁₈ aryl, and R⁴ is an optionally substituted C₁₋₁₈ alkyl or an optionally substituted C₁₋₁₈ alkoxy.

In one aspect, the repeating unit of Formula 3A or Formula 3B is represented by at least one of the following formula:

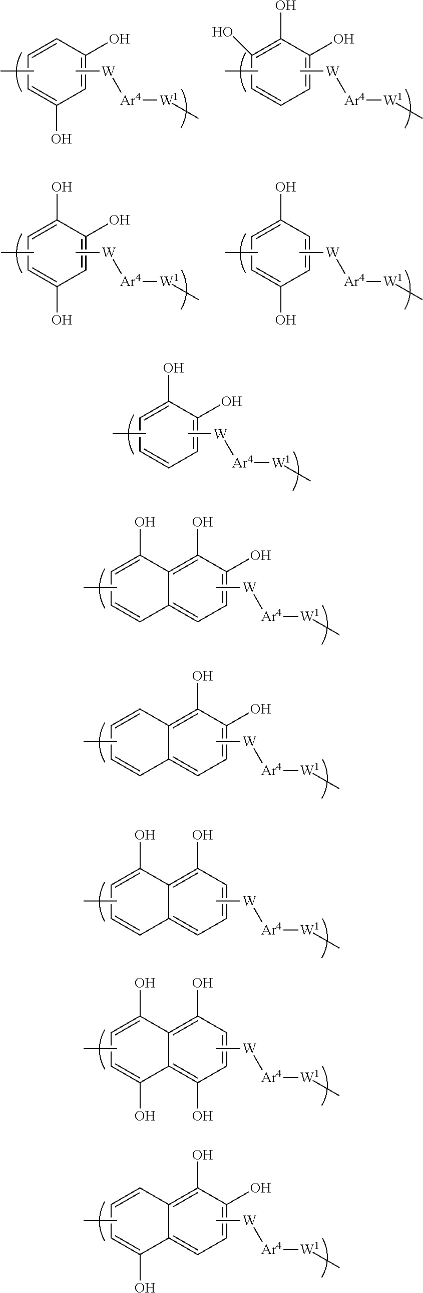

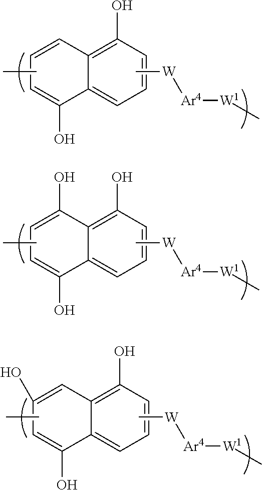

Exemplary repeating units of Formula 1A may include one or more of the following.

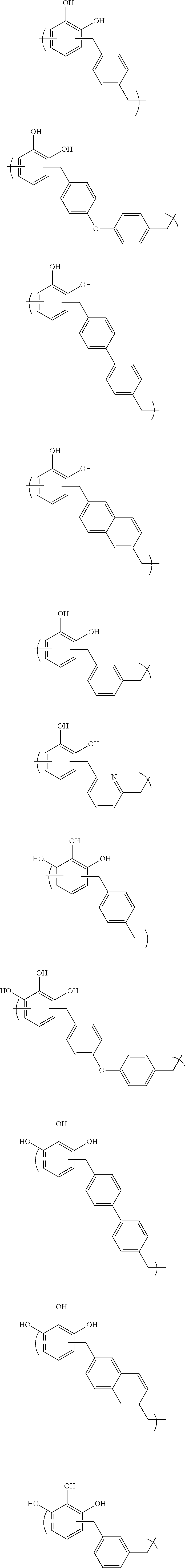

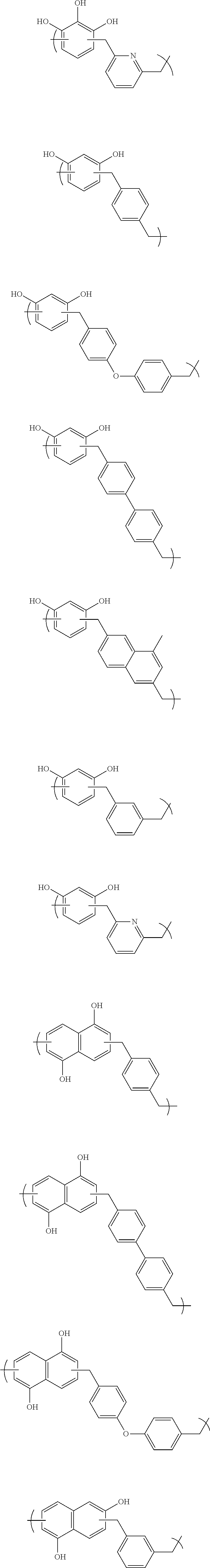

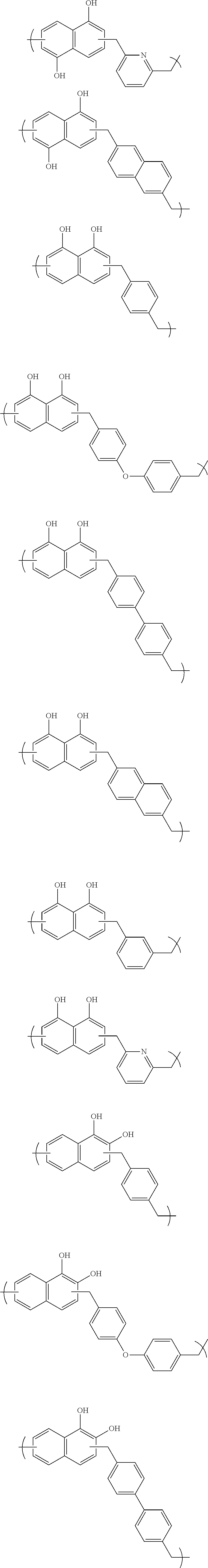

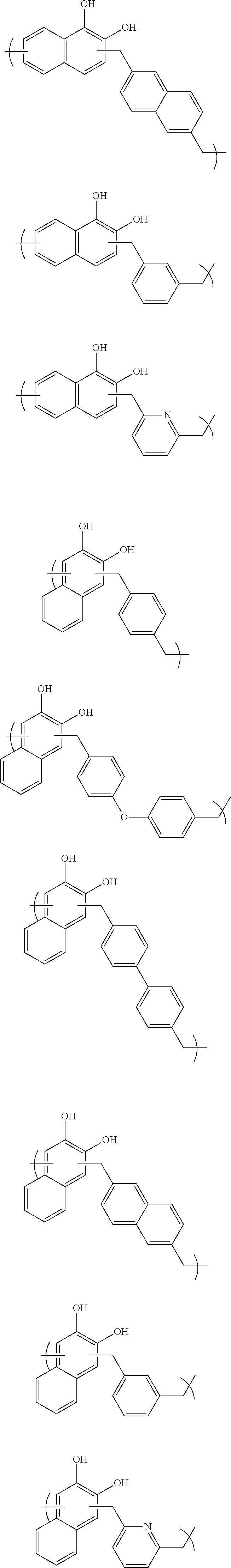

The polymer with repeating units of at least one of Formula 1, Formula 1A, or Formula 1B may also comprise a repeating unit with a pendant group that includes one or more hydroxy groups. For example, the repeating unit with a pendant group that includes one or more hydroxy groups may include 1 to 4 hydroxy groups, preferably 1 to 3 hydroxy groups, and more typically 1 or 2 hydroxy groups. In some aspects, the polymer may include two or more different repeating units with pendant groups that include one or more hydroxy groups.

Another exemplary monomer for providing repeating units with pendant groups that include one or more hydroxy groups includes the following N-hydroxyaryl maleimide monomers of Formula 4.

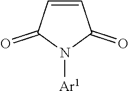

wherein in Formula 4,

Ar¹ is a hydroxy-substituted C₆₋₃₀ aryl group, a hydroxy-substituted C₃₋₃₀ heteroaryl group, or a combination thereof, each of which can be optionally substituted. It may be desired for Ar¹ to include a single hydroxyl group or two or more hydroxyl groups.

Non-limiting examples of N-hydroxyaryl maleimide monomers include the following:

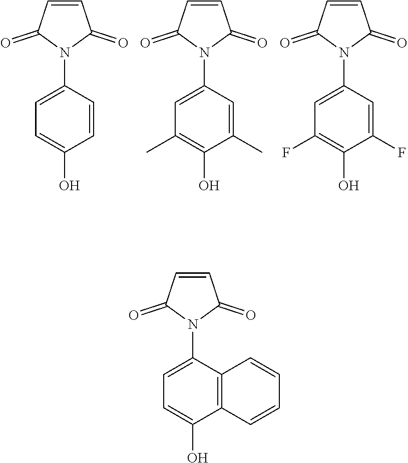

The polymer that includes a repeating unit represented by Formula 1, Formula 1A, Formula 1B, Formula 3A, or Formula 3B is present in the polymer in an amount from 10 to 100 mole percent (mol %), 20 to 90 mol %, or 20 to 70 mol %, based on the total moles of repeating units in the polymer.

The polymer that includes a repeating unit represented by Formula 1, Formula 1A, Formula 1B, Formula 3A, or Formula 3B is present in the composition, e.g., a photoresist underlayer composition, in an amount from 5 to 95 weight percent (wt %), based on the total solids of the composition, more typically in an amount from 15 to 85 wt %, 20 to 60%, or 25 to 50 wt %, based on the total solid content of the composition. As used herein, the “total solids” of the composition refers to all materials and components of the composition except for the solvent.

As noted, the composition, e.g., a resist underlayer composition, further includes a compound comprising a substituent group represented by Formula 2, hereinafter, “Formula 2 compound”. The Formula 2 compound is present in the composition in an amount from 5 to 95 wt %, based on the total solids of the composition. For example, a Formula 2 compound is present in the composition in an amount from 20 to 80 wt %, 30 to 80 wt %, 40 to 80 wt %, or 50 to 75 wt %, based on the total solid content of the composition.

In terms of a weight ratio of the polymer including a repeating unit with two or more hydroxy groups of Formula 1 to the compound including an aromatic substituent group represented by Formula 2, the weight ratio of polymer to compound is in a range of 4:1 to 1:20. Exemplary weight ratios of polymer to compound include, but is not limited to, 3:1, 2:1, 1:1, 1:1.5, 1:2, 1:3, 1:4, 1:6, or 1:10. For example, the weight ratio of polymer to compound is in a range of 2:1 to 1:4, 1:1 to 1:4, or 1:1.2 to 1:4.

In one aspect, the polymer that includes a repeating unit represented by Formula 1, Formula 1A, Formula 1B, Formula 3A, or Formula 3B may have a weight average molecular weight (M_{w}) of 1,000 to 100,000 grams per mole (g/mol), 3,000 to 60,000 g/mol, or a number average molecular weight (Mₙ) of 500 to 100,000 g/mol. Molecular weights (either M_{w} or Mₙ) are suitably determined by gel permeation chromatography (GPC) using polystyrene standards. Exemplary polymers including a repeating unit represented by Formula 1, Formula 1A, Formula 1B, Formula 3A, or Formula 3B may have a weight average molecular weight of 1,000 to 20,000 g/mol, 2,000 to 12,000 g/mol, or 2,000 to 8,000 g/mol.

In one aspect, exemplary polymer including a repeating unit represented by Formula 1, Formula 1A, Formula 1B, Formula 3A, or Formula 3B may have a weight average molecular weight of 1,000 to 8,000 g/mol, and a weight ratio of polymer to compound in a range of 2:1 to 1:4 or 1:1 to 1:4.

The composition, e.g., a photoresist underlayer composition, may also include an additive having multiple phenolic hydroxy groups to increase phenolic density. The additive can be used in photoresist underlayer compositions to provide even greater adhesion to substrates or to further enhance the mechanical properties of the resulting underlayer film. It is believed that the multiple phenolic hydroxy groups of the additive enhance the adhesion of the underlayer film to a substrate, particularly when the film and substrate are submerged into a hydrogen peroxide/ammonium hydroxide (SC-1) bath.

According to an aspect of the invention, a photoresist underlayer composition is provided that includes a polymer that includes a repeating unit represented by Formula 1, Formula 1A, Formula 1B, Formula 3A, or Formula 3B, a compound comprising a substituent group represented by Formula 2, and an additive. The additive can include a compound of Formula 5 as described below, a compound of Formula 6 as described below, or a combination thereof.

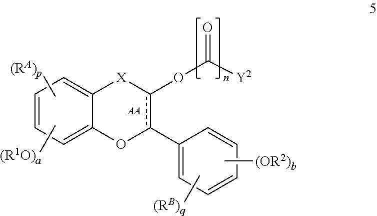

In Formula 5, AA, X, R¹, R², Y², a, and n

AA is a single bond or a double bond, and it is to be understood that “AA” refers to the moiety having the structure represented by [symbol] in Formula (5);

X is a single bond, —C(O)—, unsubstituted Ci alkylene, or hydroxy-substituted C₁ alkylene. It is to be understood that the “hydroxy-substituted C₁ alkylene” is not further substituted with a group other than hydroxy. For example, X may be —C(O)— or unsubstituted C₁ alkylene;

R¹ and R² are each independently hydrogen, substituted or unsubstituted C₁₋₃₀ alkyl, substituted or unsubstituted C₃₋₃₀ cycloalkyl, —C(O)OR^{5a}, or glycidyl, wherein R^{5a} is hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl. Typically, R¹ and R² may be hydrogen.

Y² is hydrogen, substituted or unsubstituted C₆₋₆₀ aryl, or substituted or unsubstituted C₁₋₆₀ heteroaryl. It is to be understood that when n is 0, the oxygen atom is directly bonded to group Y² to form a partial structure represented by —O—Y². In some aspects, n is 0 and Y² is hydrogen. In other aspects, n is 1 and Y² is substituted or unsubstituted C₆₋₃₀ aryl, preferably a C₆₋₃₀ aryl substituted with two or more hydroxy groups, for example 2, 3, or 4 hydroxy groups, typically from 2 to 3 hydroxy groups, wherein the C₆₋₃₀ aryl group optionally may be further substituted with one or more substituent groups that are not hydroxy

and each R^{A} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl; each R^{B} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl; and

a is 2, 3, or 4, typically 2 or 3; b is 2, 3, 4, or 5, preferably from 2, 3, or 4; p is 0, 1, or 2, typically 0 or 1; and q is 0, 1, 2, or 3, typically 0 or 1; m is an integer from 1 to 6, typically from 1, 2, or 3; and n is 0 or 1.

In some aspects, the additives of Formula 5 may be represented by a compound selected from Formula 5A, Formula 5B, or a combination thereof:

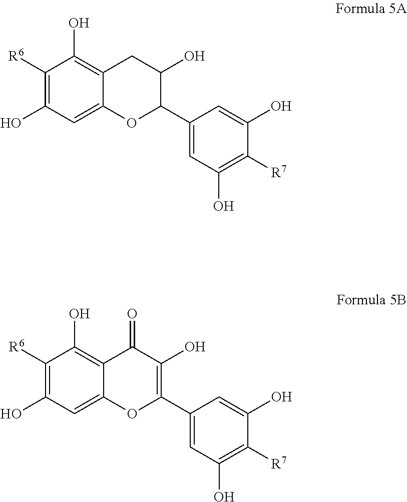

wherein in Formula 5A or Formula 5B

R⁶ is hydrogen, substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl; and

R⁷ is hydrogen, substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl.

Exemplary additives of Formula 5 may include one or more compounds selected from:

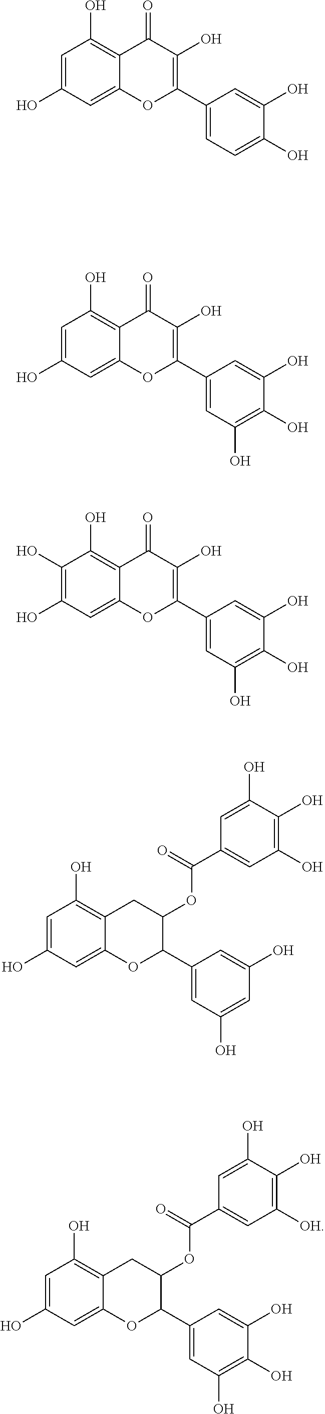 [SMILES: O=c1c(O)c(-c2ccc(O)c(O)c2)oc2cc(O)cc(O)c12 ; O=c1c(O)c(-c2cc(O)c(O)c(O)c2)oc2cc(O)cc(O)c12 ; O=c1c(O)c(-c2cc(O)c(O)c(O)c2)oc2cc(O)c(O)c(O)c12 ; O=C(OC1Cc2c(O)cc(O)cc2OC1c1cc(O)cc(O)c1)c1cc(O)c(O)c(O)c1 ; O=C(OC1Cc2c(O)cc(O)cc2OC1c1cc(O)c(O)c(O)c1)c1cc(O)c(O)c(O)c1]

In some aspects, the additive is represented by Formula 6.

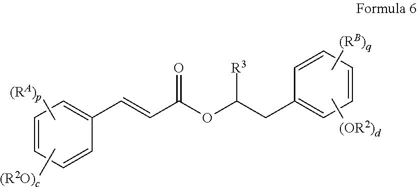

In Formula 6, R², and R^{B} is the same as R^{A}, as defined for Formula 5, and R³ may be hydrogen, a carboxylic acid group or a derivative thereof, or —C(O)OR^{5b}, preferably a carboxylic acid group or a derivative thereof. As used herein, “carboxylic acid or derivative thereof” refers to a carboxylic acid (—COOH) or a carboxylic acid derivative of the formula —COO⁻M⁺, wherein M⁺ is a cationic organic or inorganic group, for example an alkylammonium cation;

c and d are each independently an integer from 2 to 5, typically 2, 3, or 4; p is 0, 1, or 2, typically 0 or 1; and q is 0, 1, 2, or 3, typically 0 or 1.

In some aspects, the additives of Formula 6 may be represented by a compound of Formula 6a, Formula 6B, or a combination thereof:

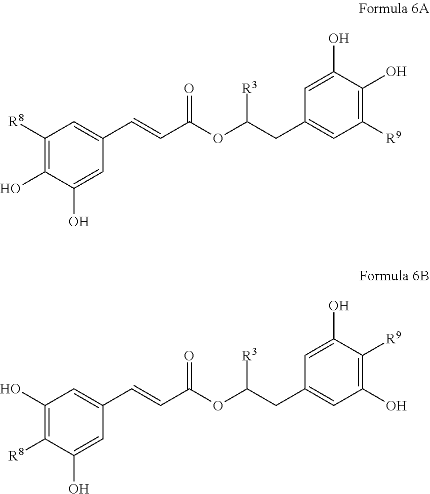

wherein in Formula 6A or Formula 6B;

R⁸ is hydrogen, substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl; and

R⁹ is hydrogen, substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl; and

each R³ is the same as defined for Formula 6.

Exemplary additives of Formula 6 may include one or more compounds selected from:

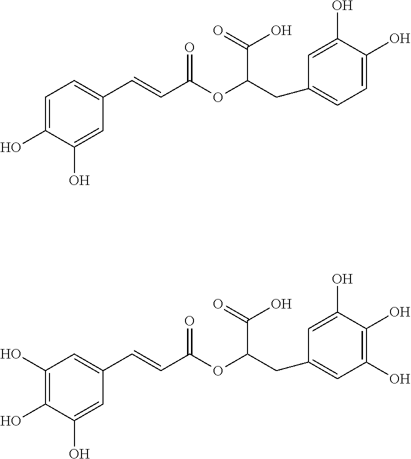 [SMILES: O=C(/C=C/c1ccc(O)c(O)c1)OC(Cc1ccc(O)c(O)c1)C(=O)O ; O=C(/C=C/c1cc(O)c(O)c(O)c1)OC(Cc1cc(O)c(O)c(O)c1)C(=O)O]

The additive may be included in the photoresist underlayer composition in an amount from 0.1 to 20 wt %, typically 1 to 20 wt % or 5 to 20 wt %, based on total solids of the photoresist underlayer composition.

The composition, e.g., a photoresist underlayer composition, may also include an additive that includes a nitrogen atom that is attached to a thermally-cleavable protecting group or an acid-cleavable protecting group. At times, such additives are referred to in the art as thermal base generating compounds or a thermal base generating polymers. The cleavable protecting group is typically cleaved during the curing of the composition, and the exposed nitrogen atom may enhance the adhesion of the underlayer film to a substrate, particularly when the film and substrate are submerged into a hydrogen peroxide/ammonium hydroxide (SC-1) bath.

In an embodiment, the thermal base generating compound, or a thermal base generating polymer, includes a protected amino group, which can be derived from a primary or secondary amino moiety. Various amine protecting groups are suitable for use in the present invention, provided such protecting groups are removable (cleavable) by heat, acid, or a combination thereof. The amine protecting group is thermally cleavable such as at a temperature from 75 to 350° C., including from 100 to 250° C.

Suitable amine protecting groups useful in the present invention include carbamates such as 9-fluorenylmethyl carbamates, t-butyl carbamates, and benzyl carbamates; amides such as acetamides, trifluoroacetamides and p-toluenesulfonamides; benzylamines; triphenylmethylamines (tritylamines); and benzylideneamines. Such amine protecting groups, their formation and their removal are well-known in the art. See, for example, T. W. Green et al., Protective Groups in Organic Synthesis, Wiley-Interscience, New York, 1999.

In an embodiment, the thermal base generating compound is represented by Formula 7. In an embodiment, the thermal base polymer may include a repeating unit derived from a monomer of Formula 8. Alternatively, the composition described herein can include a combination of a compound of Formula 7 and a polymer derived from a monomer of Formula 8.

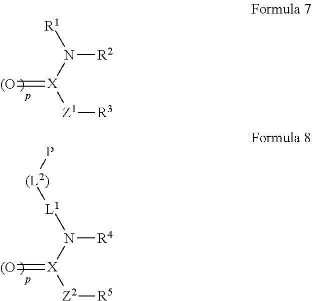

In Formulae 7 and 8, X is C or S, wherein when X is C, then p is 1, and when X is S, then p is 2. Typically, X is C.

In Formulae 7 and 8, Z¹, Z², L¹, and L² are each independently a single bond or a divalent linking group. For example, Z¹, Z², L¹, and L² each independently may be a single bond or a divalent linking group comprising one or more of substituted or unsubstituted C₁₋₃₀ alkylene, substituted or unsubstituted C₁₋₃₀ heteroalkylene, substituted or unsubstituted C₃₋₃₀ cycloalkylene, substituted or unsubstituted C₂₋₃₀ heterocycloalkylene, substituted or unsubstituted C₆₋₃₀ arylene, substituted or unsubstituted C₁₋₃₀ heteroarylene, —O—, —C(O)—, —N(R^{4a})—, —S—, or —S(O)₂—, wherein R^{4a} may be hydrogen, substituted or unsubstituted C₁₋₂₀ alkyl, substituted or unsubstituted C₆₋₃₀ aryl, substituted or unsubstituted C₁₋₃₀ heteroaryl, or substituted or unsubstituted C₂₋₃₀ heteroarylalkyl. Preferably, Z¹ and Z² are each independently O—.

In Formulae 7 and 8, R¹ and R² each independently may be hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₆₋₃₀ aryl, or substituted or unsubstituted C₁₋₃₀ heteroaryl. Optionally, R¹ and R² may together form a ring via a divalent linking group.

In Formulae 7 and 8, R³ and R⁵ each independently may be hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₆₋₃₀ aryl, substituted or unsubstituted C₁₋₃₀ heteroaryl, —OR^{4c}, or —N(R^{4d})(R^{4e}), wherein R^{4c}, R^{4d}, and R^{4e} are each independently hydrogen, substituted or unsubstituted C₁₋₂₀ alkyl, substituted or unsubstituted C₆₋₃₀ aryl, or substituted or unsubstituted C₁₋₃₀ heteroaryl. Optionally, in Formula 8, L¹ and R⁴ together may form a ring via a divalent linking group, for example a divalent linking group.

In Formula 8, P is a polymerizable group. Typically, the polymerizable group may be chosen from carboxyl, thiol, amino, epoxy, alkoxy, amido, vinyl, or a combination thereof.

The additive may be included in the composition in an amount from 0.1 to 20 wt %, typically 1 to 20 wt % or 5 to 20 wt %, based on total solids of the composition.

In an embodiment we describe a method of forming a pattern, e.g., a pattern in a semiconductor device. The method including:
applying a photoresist underlayer composition over a substrate to provide a photoresist underlayer;
forming a photoresist layer over the photoresist underlayer;
patterning the photoresist layer; and
transferring a pattern from the patterned photoresist layer to the photoresist underlayer;
wherein the photoresist underlayer composition comprises a polymer that includes a repeating unit represented by Formula 1, a compound including a substituent group represented by Formula 2; and a solvent;

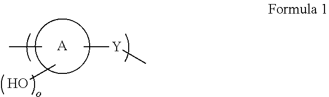

wherein in Formula 1

Ring A represents an aromatic ring group with one to six independently substituted or unsubstituted aromatic rings, wherein optionally, two or more of the aromatic rings are fused, one or more aromatic rings includes a fused optionally substituted cycloalkyl or an optionally substituted fused heterocycloalkyl, or a combination thereof,

Y is a divalent group comprising an optionally substituted C₁₋₄ alkylene, —O—, —S—, C(O)—, an optionally substituted arylene, or an optionally substituted heteroarylene, with one or two aromatic rings, or a combination thereof, and

o is an integer from 2 to 8;

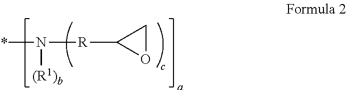

wherein, in Formula 2:

R is a substituted or unsubstituted C₁₋₄ alkylene, —CR^{A}R^{B}—Ar—CH₂—, or —Ar—CH₂—, where Ar is an optionally substituted arylene or heteroarylene with 4 to 10 ring carbons, and R^{A} and R^{B} are independently hydrogen, hydroxy, optionally substituted C₁₋₆ alkyl, optionally substituted C₁₋₆ alkoxy, or optionally substituted C₆₋₁₂ aryl;

R¹ is hydrogen, an optionally substituted C₁₋₄ alkyl, an optionally substituted C₆₋₁₂ aryl, an optionally substituted C₃₋₈ cycloalkyl, or glycidyl;

* is a connection point to a ring carbon of aromatic ring system Q, wherein the aromatic ring system Q is Ar¹ or Ar²-T-Ar³,

wherein Ar¹, Ar², and Ar³ comprise independently a substituted or unsubstituted aromatic group with 4 to 14 ring carbons, and

T is absent, —O—, —S—, —C(O)—, an optionally substituted C₁₋₄ alkylene, or —NR²—, wherein R² is hydrogen, an optionally substituted C₁₋₄ alkyl, or an optionally substituted C₆₋₁₂ aryl; and

a is 1 to 8, c is 1, 2, or 3, and b+c is 2 or 3.

Moreover, the above prepared photoresist underlayer composition would be free of non-polymeric polyphenol compounds and thermal base generators. As understood by those of ordinary skill in the art, the reference to non-polymeric polyphenol compounds would include the additive compounds of Formula 5 and Formula 6 above, and the reference to thermal base generators would include the compounds of Formula 7 above and polymers of Formula 8 above, respectively.

Suitable polymers of the present invention can be readily prepared based on and by analogy with the procedures described in the examples of the present application, which are readily understood by those of ordinary skill in the art. For example, one or more monomers corresponding to the repeating units described herein may be combined, or fed separately, using suitable solvent(s) and initiator, and polymerized in a reactor. The monomer composition may further include additives, such as a solvent, a polymerization initiator, a curing catalyst (i.e., the acid catalyst), and the like. For example, the polymer may be obtained by polymerization of the respective monomers under any suitable conditions, such as by heating at an effective temperature, irradiation with activating radiation at an effective wavelength, or a combination thereof.

The photoresist underlayer composition may further include one or more polymers (“additional polymers”) in addition to the polymers described above. For example, the photoresist underlayer composition may further include an additional polymer as described above but different in composition. Additionally, or alternatively, the one or more additional polymers can include those well known in the art, for example, one or more polymers selected from polyacrylates, polyvinylethers, polyesters, polynorbornenes, polyacetals, polyethylene glycols, polyamides, polyacrylamides, polyphenols, novolacs, styrenic polymers, polyvinyl alcohols, copolymers thereof, and combination thereof.

In some aspects, the photoresist underlayer composition may further include one or more curing agents to aid in the curing of the photoresist underlayer composition, for example after the photoresist underlayer composition has been applied to a surface. A curing agent is any component which causes curing of the photoresist underlayer composition on the surface of a substrate.

It may be beneficial to include an acid generator compound such as a photoacid generator (PAG) and/or a thermal acid generator (TAG) compound in the photoresist underlayer compositions. Preferred curing agents are thermal acid generators (TAGs).

Suitable PAGs are known in the art of chemically amplified photoresists and include, for example: onium salts, for example, triphenylsulfonium trifluoromethanesulfonate, (p-tert-butoxyphenyl)diphenylsulfonium trifluoromethanesulfonate, tris(p-tert-butoxyphenyl)sulfonium trifluoromethanesulfonate, triphenylsulfonium p-toluenesulfonate; nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine. One or more of such PAGs can be used.

A TAG compound is any compound that liberates acid upon exposure to heat. Exemplary thermal acid generators include, without limitation, amine blocked strong acids, such as amine blocked sulfonic acids such as amine blocked dodecylbenzenesulfonic acid. It will also be appreciated by those skilled in the art that certain photoacid generators are able to liberate acid upon heating and may function as thermal acid generators.

Suitable TAG compounds may include, for example, nitrobenzyl tosylates, such as 2-nitrobenzyl tosylate, 2,4-dinitrobenzyl tosylate, 2,6-dinitrobenzyl tosylate, 4-nitrobenzyl tosylate; benzenesulfonates such as 2-trifluoromethyl-6-nitrobenzyl 4-chlorobenzenesulfonate, 2-trifluoromethyl-6-nitrobenzyl 4-nitro benzenesulfonate; phenolic sulfonate esters such as phenyl, 4-methoxybenzenesulfonate; alkyl ammonium salts of organic acids, such as triethylammonium salt of 10-camphorsulfonic acid, trifluoromethylbenzenesulfonic acid, perfluorobutane sulfonic acid; and particular onium salts. A variety of aromatic (anthracene, naphthalene, or benzene derivatives) sulfonic acid amine salts can be employed as the TAG, including those disclosed in U.S. Pat. Nos. 3,474,054, 4,200,729, 4,251,665 and 5,187,019. Examples of TAGs include those sold by King Industries, Norwalk, Conn. USA under NACURE, CDX and K-PURE names, for example, NACURE 5225, CDX-2168E, K-PURE 2678 and KPURE 2700. One or more of such TAGs can be used.

The amount of such curing agents useful in the present compositions may be, for example, from greater than 0 to 10 wt %, and typically from greater than 0 to 3 wt % based on total solids of the photoresist underlayer composition.

In some aspects, the photoresist underlayer composition does not include a photoacid generator. Accordingly, in these embodiments the photoresist underlayer composition may be substantially free of a PAG compound and/or a polymeric PAG, for example free of a PAG compound or polymeric PAG.

The photoresist underlayer composition may further include one or more crosslinking agents, for example a crosslinking agent that includes non-epoxy crosslinkers. Any suitable crosslinking agent may be further used in the present coating compositions, provided that such crosslinking agent has at least 2, and preferably at least 3, moieties capable of reacting with functional groups in the photoresist underlayer composition. Exemplary crosslinking agents may include novolac resins, melamine compounds, guanamine compounds, isocyanate-containing compounds, benzocyclobutenes, benzoxazines, and the like, and typically any of the foregoing having 2 or more, more typically 3 or more substituents selected from methylol, C₁₋₁₀ alkoxymethyl, and C₂₋₁₀ acyloxymethyl. Examples of suitable crosslinking agents include those shown below:

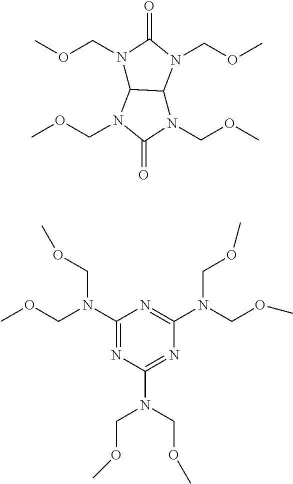

The additional crosslinking agents are well-known in the art and are commercially available from a variety of sources. The amount of such additional crosslinking agents useful in the present coating compositions may be, for example, in the range from greater than 0 to 30 wt %, and preferably from greater than 0 to 10 wt % based on total solids of the coating composition.

The photoresist underlayer composition may include one or more optional additives including, for example, surfactants, antioxidant, or the like, or a combination thereof. When present, each optional additive may be used in the photoresist underlayer composition in minor amounts such as from 0.01 to 10 wt %, based on total solids of the photoresist underlayer composition.

Typical surfactants include those which exhibit an amphiphilic nature, meaning that they may be both hydrophilic and hydrophobic at the same time. Amphiphilic surfactants possess a hydrophilic head group or groups, which have a strong affinity for water and a long hydrophobic tail, which is organophilic and repels water. Suitable surfactants may be ionic (i.e., anionic, cationic) or nonionic. Further examples of surfactants include silicone surfactants, poly(alkylene oxide) surfactants, and fluorochemical surfactants. Suitable non-ionic surfactants include, but are not limited to, octyl and nonyl phenol ethoxylates such as TRITON X-114, X-100, X-45, X-15 and branched secondary alcohol ethoxylates such as TERGITOL TMN-6 (The Dow Chemical Company, Midland, Mich. USA). Still further exemplary surfactants include alcohol (primary and secondary) ethoxylates, amine ethoxylates, glucosides, glucamine, polyethylene glycols, poly(ethylene glycol-co-propylene glycol), or other surfactants disclosed in McCutcheon's Emulsifiers and Detergents, North American Edition for the Year 2000 published by Manufacturers Confectioners Publishing Co. of Glen Rock, N.J. Nonionic surfactants that are acetylenic diol derivatives also may be suitable. Such surfactants are commercially available from Air Products and Chemicals, Inc. of Allentown, Pa. and sold under the trade names of SURFYNOL and DYNOL. Additional suitable surfactants include other polymeric compounds such as the tri-block EO-PO-EO co-polymers PLURONIC 25R2, L121, L123, L31, L81, L101, and P123 (BASF, Inc.).

An antioxidant can be added to prevent or minimize oxidation of organic materials in the photoresist underlayer composition. Suitable antioxidants include, for example, phenol-based antioxidants, antioxidants composed of an organic acid derivative, sulfur-containing antioxidants, phosphorus-based antioxidants, amine-based antioxidants, antioxidant composed of an amine-aldehyde condensate and antioxidants composed of an amine-ketone condensate. Examples of the phenol-based antioxidant include substituted phenols such as 1-oxy-3-methyl-4-isopropylbenzene, 2,6-di-tert-butylphenol, 2,6-di-tert-butyl-4-ethylphenol, 2,6-di-tert-butyl methylphenol, 4-hydroxymethyl-2,6-di-tert-butylphenol, butyl.hydroxyanisole, 2-(1-methylcyclohexyl)-4,6-dimethylphenol, 2,4-dimethyl-6-tert-butylphenol, 2-methyl-4,6- dinonylphenol, 2,6-di-tert-butyl-α-dimethylamino-p-cresol, 6-(4-hydroxy-3,5-di-tert- butyl.anilino)2,4-bis.octyl-thio-1,3,5-triazine, n-octadecyl-3-(4′-hydroxy-3′,5′-di-tert- butyl.phenyl)propionate, octylated phenol, aralkyl-substituted phenols, alkylated p-cresol and hindered phenol; bis-, tris- and poly-phenols such as 4,4′-bisphenol, 4,4′-methylene-bis-(dimethyl-4,6-phenol), 2,2′-methylene-bis-(4-methyl-6-tert-butylphenol), 2,2′-methylene-bis-(4- methyl-6-cyclohexylphenol), 2,2′-methylene-bis-(4-ethyl-6-tert-butylphenol), 4,4′-methylene- bis-(2,6-di-tert-butylphenol), 2,2′-methylene-bis-(6-α-methyl-benzyl-p-cresol), methylene-crosslinked polyvalent alkylphenol, 4,4′-butylidene-bis-(3-methyl-6-tert-butylphenol), 1,1-bis-(4-hydroxyphenyl)-cyclohexane, 2,2′-dihydroxy-3,3′-di-(α-methylcyclohexyl)-5,5′-dimethyl.diphenylmethane, alkylated bisphenol, hindered bisphenol, 1,3,5-trimethyl-2,4,6-tris(3,5-di-tert-butyl-4-hydroxybenzyl)benzene, tris-(2-methyl-4-hydroxy-5-tert-butylphenyl)butane, and tetrakis-[methylene-3-(3′,5′-di-tert-butyl-4′-hydroxyphenyl) propionate]methane. Suitable antioxidants are commercially available, for example, Irganox™ antioxidants (Ciba Specialty Chemicals Corp.).

The photoresist underlayer composition includes a solvent. The solvent component may be a single solvent or may include a mixture of two or more distinct solvents. Suitably, each of the multiple solvents may be miscible with each other. Suitable solvents include, for example, one or more oxyisobutyric acid esters, particularly methyl-2-hydroxyisobutyrate, 2-hydroxyisobutyric acid, and ethyl lactate; one or more of glycol ethers, particularly 2-methoxyethyl ether (diglyme), ethylene glycol monomethyl ether, and propylene glycol monomethyl ether; one or more solvents that have both ether and hydroxy moieties, particularly methoxy butanol, ethoxy butanol, methoxy propanol, and ethoxy propanol; one or more alkyl esters, particularly methyl cellosolve acetate, ethyl cellosolve acetate, propylene glycol monomethyl ether acetate, and dipropylene glycol monomethyl ether acetate and other solvents such as one or more dibasic esters; and/or other solvents such as one or more of propylene carbonate and gamma-butyro lactone.

The desired total solids of the photoresist underlayer composition will depend on factors such as the desired final layer thickness. Typically, the total solids of the photoresist underlayer composition may be from 0.1 to 20 wt %, for example, from 0.1 to 10 wt %, more typically, from 0.11 to 5 wt %, based on the total weight of the coating composition.

The photoresist underlayer composition may be prepared following known procedures. For example, the photoresist underlayer composition may be prepared by combining the first material, the second material, the additive, the solvent, and any optional components, in any order. The photoresist underlayer composition may be used as is, or may be subjected to purification or dilution prior to being coated on the substrate. Purification may involve, for example, one or more of centrifugation, filtration, distillation, decantation, evaporation, treatment with ion exchange beads, and the like.

The patterning methods of the present invention comprise applying a layer of the photoresist underlayer composition over a substrate; curing the applied photoresist underlayer composition to form a coated underlayer; and forming a photoresist layer over the coated underlayer. The method may further include the steps of pattern-wise exposing the photoresist layer to activating radiation; and developing the exposed photoresist layer to provide a resist relief image. In some aspects, the method may further include forming a silicon-containing layer, an organic antireflective coating layer, or a combination thereof, over the coated underlayer prior to forming the photoresist layer. In some aspects, the method may further include transferring the pattern to the silicon-containing layer, the organic antireflective coating layer, or the combination thereof, after developing an exposed photoresist layer and before the step transferring the pattern to the coated underlayer.

A wide variety of substrates may be used in the patterning methods, with electronic device substrates being typical. Suitable substrates include, for example, packaging substrates such as multichip modules; flat panel display substrates; integrated circuit substrates; substrates for light emitting diodes (LEDs) including organic light emitting diodes (OLEDs); semiconductor wafers; polycrystalline silicon substrates; and the like. Suitable substrates may be in the form of wafers such as those used in the manufacture of integrated circuits, optical sensors, flat panel displays, integrated optical circuits, and LEDs. As used herein, the term “semiconductor wafer” is intended to encompass “an electronic device substrate,” “a semiconductor substrate,” “a semiconductor device,” and various packages for various levels of interconnection, including a single-chip wafer, multiple-chip wafer, packages for various levels, or other assemblies requiring solder connections. Such substrates may be any suitable size. Typical wafer substrate diameters are 200 mm to 300 mm, although wafers having smaller and larger diameters may be suitably employed according to the present invention. As used herein, the term “semiconductor substrate” includes any substrate having one or more semiconductor layers or structures which may optionally include active or operable portions of semiconductor devices. A semiconductor device refers to a semiconductor substrate upon which at least one microelectronic device has been or is being batch fabricated.

The substrates are typically composed of one or more of silicon, polysilicon, silicon oxide, silicon nitride, silicon oxynitride, silicon germanium, gallium arsenide, aluminum, sapphire, tungsten, titanium, titanium-tungsten, nickel, copper, and gold. The substrate may include one or more layers and patterned features. The layers may include, for example, one or more conductive layers such as layers of aluminum, copper, molybdenum, tantalum, titanium, tungsten, alloys, nitrides, or silicides of such metals, doped amorphous silicon or doped polysilicon, one or more dielectric layers such as layers of silicon oxide, silicon nitride, silicon oxynitride, or metal oxides, semiconductor layers, such as single-crystal silicon, and combinations thereof. In some aspects, the substrate includes titanium nitride. The layers can be formed by various techniques, for example, chemical vapor deposition (CVD) such as plasma-enhanced CVD (PECVD), low-pressure CVD (LPCVD) or epitaxial growth, physical vapor deposition (PVD) such as sputtering or evaporation, or electroplating.

It may be desired in certain patterning methods of the invention to provide one or more lithographic layers such as a hardmask layer, for example, a spin-on-carbon (SOC), amorphous carbon, or metal hardmask layer, a CVD layer such as a silicon nitride (SiN) layer, silicon oxide (SiO) layer, or silicon oxynitride (SiON) layer, an organic or inorganic BARC layer, or a combination thereof, on an upper surface of the substrate prior to forming the photoresist underlayer of the invention. Such layers, together with a layer of the photoresist underlayer composition of the invention and photoresist layer, form a lithographic material stack. Typical lithographic stacks which may be used in the patterning methods of the invention include, for example, the following: SOC layer/underlayer/photoresist layer; SOC layer/SiON layer/underlayer/photoresist layer; SOC layer/SiARC layer/underlayer/photoresist layer; SOC layer/metal hardmask layer/underlayer/photoresist layer; amorphous carbon layer/underlayer/photoresist layer; and amorphous carbon layer/SiON layer/underlayer/photoresist layer.

It is to be understood that the “photoresist underlayer,” as used herein, refers to the one or more layers that are disposed between the substrate and the photoresist layer (i.e., “above the substrate”). Accordingly, the inventive coated underlayer (i.e., a layer of the photoresist underlayer composition) may be used alone as a photoresist underlayer, or the inventive coated underlayer (i.e., a layer of the photoresist underlayer composition) may be used in conjunction with other underlayers, including those as described herein.

The photoresist underlayer composition may be coated on the substrate by any suitable means, such as spin-coating, slot-die coating, doctor blading, curtain-coating, roller-coating, spray-coating, dip-coating, and the like. In the case of a semiconductor wafer, spin-coating is preferred. In a typical spin-coating method, the present compositions are applied to a substrate which is spinning at a rate of 500 to 4000 revolutions per minute (rpm) for a period of 15 to 90 seconds to obtain a desired layer of the condensed polymer on the substrate. It will be appreciated by those skilled in the art that the thickness of the coated layer may be adjusted by changing the spin speed, as well as the solids content of the composition. An underlayer formed from the photoresist underlayer composition typically has a dried layer thickness from 1 to 50 nanometers (nm), more typically from 1 to 10 nm.

The coated photoresist underlayer composition is optionally softbaked at a relatively low temperature to remove any solvent and other relatively volatile components. Typically, the substrate is baked at a temperature of less than or equal to 150° C., preferably from 60 to 125° C., and more preferably from 90 to 115° C. The baking time is typically from 10 seconds to 10 minutes, preferably from 30 seconds to 5 minutes, and more preferably from 6 to 90 seconds. When the substrate is a wafer, such baking step may be performed by heating the wafer on a hot plate. Such soft-baking step may be performed as part of the curing of the coating layer, or may be omitted altogether.

The photoresist underlayer composition is then cured to form a coated underlayer. The coating composition should be sufficiently cured such that the coated underlayer film does not intermix, or minimally intermixes, with another underlayer component or the photoresist layer to be formed above the underlayer. The coated composition may be cured in an oxygen-containing atmosphere, such as air, or in an inert atmosphere, such as nitrogen and under conditions, such as heating, sufficient to provide a cured coating layer. This curing step is preferably conducted on a hot plate-style apparatus, although oven curing may be used to obtain equivalent results. Typically, the curing may be conducted at a temperature of 150° C. or greater, and preferably 150 to 450° C. It is more preferred that the curing temperature is 180° C. or greater, still more preferably 200° C. or greater, and even more preferably from 200 to 400° C. The curing time is typically from 10 seconds to 10 minutes, preferably from 30 seconds to 5 minutes, more preferably from 45 seconds to 2 minutes, and still more preferably from 45 to 90 seconds. Optionally, a ramped or a multi-stage curing process may be used. A ramped bake typically begins at a relatively low (e.g., ambient) temperature that is increased at a constant or varied ramp rate to a higher target temperature. A multi-stage curing process involves curing at two or more temperature plateaus, typically a first stage at a lower bake temperature and one or more additional stages at a higher temperature. Conditions for such ramped or multi-stage curing processes are known to those skilled in the art, and may allow for omission of a preceding soft bake process.

After curing of the applied photoresist underlayer composition, a photoresist layer is formed over the coated underlayer. As noted above, other intervening layers may be applied between the coated underlayer and the overcoated photoresist layer. In some aspect, the method may further include forming a silicon-containing layer, an organic antireflective coating layer, or a combination thereof, over the coated underlayer prior to forming the photoresist layer.

A wide variety of photoresists may be suitably used in the methods of the invention and are typically positive-tone materials. The particular photoresists to be used will depend on the exposure wavelength used and generally comprise an acid-sensitive matrix polymer, a photoactive component such as a photoacid generator, a solvent, and optional additional components. Suitable photoresists are known to those skilled in the art and are commercially available, for example, various photoresist materials in the UV™ and EPIC™ product families from DuPont Electronics & Industrial. The photoresist can be applied to the substrate by known coating techniques such as described above with reference to the underlayer composition, with spin-coating being typical. A typical thickness for the photoresist layer is from 10 to 300 nm. The photoresist layer is typically next soft baked to minimize the solvent content in the layer, thereby forming a tack-free coating and improving adhesion of the layer to the substrate. The soft bake can be conducted on a hotplate or in an oven, with a hotplate being typical. Typical soft bakes are conducted at a temperature from 70 to 150° C., and a time from 30 to 90 seconds.

The photoresist layer is next exposed to activating radiation through a photomask to create a difference in solubility between exposed and unexposed regions. References herein to exposing a photoresist composition to radiation that is activating for the composition indicates that the radiation is capable of forming a latent image in the photoresist composition. The photomask has optically transparent and optically opaque regions corresponding to regions of the resist layer to be exposed and unexposed, respectively, by the activating radiation. The exposure wavelength is typically sub-400 nm, and more typically, sub-300 nm, such as 248 nm (KrF), 193 nm (ArF), or an EUV wavelength (e.g., 13.5 nm). In a preferred aspect, the exposure wavelength is 193 nm or an EUV wavelength. The exposure energy is typically from 10 to 100 millijoules per square centimeter (mJ/cm²), depending, for example, on the exposure tool and the components of the photosensitive composition.

Following exposure of the photoresist layer, a post-exposure bake (PEB) is typically performed. The PEB can be conducted, for example, on a hotplate or in an oven. The PEB is typically conducted at a temperature from 70 to 150° C., and a time from 30 to 90 seconds. A latent image defined by the boundary between polarity-switched and unswitched regions (corresponding to exposed and unexposed regions, respectively) is thereby formed. The photoresist layer is next developed to remove the exposed regions of the layer, leaving the unexposed regions forming a patterned photoresist layer. The developer is typically an aqueous alkaline developer, for example, a tetra-alkyl ammonium hydroxide solution such as a tetramethylammonium hydroxide (TMAH) solution, typically a 0.26 Normality (N) (2.38 wt %) solution of TMAH. The developer may be applied by known techniques, for example, spin-coating or puddle coating.

The pattern of the photoresist layer can be transferred to one or more underlying layers including the coated underlayer and to the substrate by appropriate etching techniques, such as by plasma etching using appropriate gas species for each layer being etched. Depending on the number of layers and materials involved, pattern transfer may include multiple etching steps using different etching gases. The patterned photoresist layer, the coated underlayer, and the other optional layers in the lithographic stack may be removed following pattern transfer to the substrate using conventional techniques. Optionally, one or more of the layers of the stack may be removed following, or consumed during, pattern transfer to an underlying layer and prior to pattern transfer to the substrate. For example, pattern transfer to one or more of a silicon-containing layer, an organic antireflective coating layer, or the like may occur after the exposed photoresist layer is developed and before pattern transfer to the coated underlayer. The substrate is then further processed according to known processes in the art to form an electronic device.

Also provided is a coated substrate that includes a layer of the inventive photoresist underlayer composition on a substrate; and a photoresist layer disposed on the layer of the photoresist underlayer composition. As used herein, the term “cured layer” refers to a layer derived from the photoresist underlayer composition after the composition has been disposed on a substrate and subsequently cured to form a coating layer or film. In other words, curing the photoresist underlayer composition forms a cured layer derived from the photoresist underlayer composition.

Still other aspects provide a layered article including a coated underlayer derived from the inventive photoresist underlayer composition. In an embodiment, a layered article may include a substrate; a coated underlayer disposed over the substrate; and a photoresist layer disposed over the coated underlayer.

Photoresist underlayers, including coated underlayers prepared from the inventive photoresist underlayer composition show excellent photospeed and improved pattern collapse. Preferred photoresist underlayer compositions of the invention may, as a result, be useful in a variety of semiconductor manufacturing processes

The present inventive concept is further illustrated by the following examples, which are intended to be non-limiting. The compounds and reagents used herein are available commercially except where a procedure is provided below.

### EXAMPLES

Example A-1, which is referred to in the art as a catechol novolac (A1-CN), with a (M_{w} (GPC)=2,290 g/mol, was obtained from a commercial source.

### Synthesis Example A2:

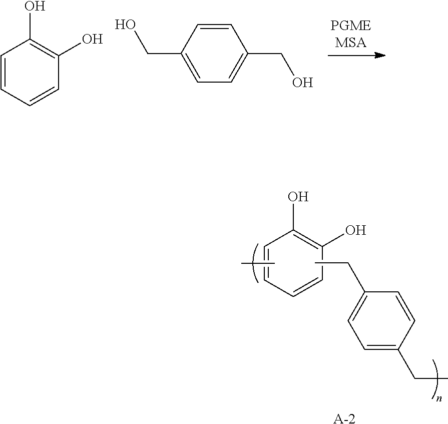

Catechol (14.98 g) and 1,4-benzenedimethanol (17.64 g) were dissolved in propylene glycol methyl ether (70 mL). Methanesulfonic acid (1.30 g) was added and the solution was heated to 120° C. for 8 hours. The solution was then cooled to room temperature and precipitated into 1 L of a 70% water/30% methanol (v/v) mixture. The liquid was decanted off and the polymer was redissolved in 50 mL tetrahydrofuran and precipitated into 500 mL heptanes. The liquid was decanted off and the polymer was dried under vacuum at 50° C. overnight, yielding 23.11 g of polymer A-2. Mw (by GPC): 3069 g/mol.

### Synthesis Example A3:

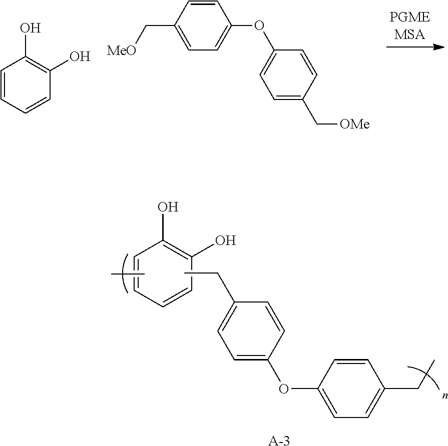

Catechol (15.00 g) and 4,4′-oxybis[(methoxymethyl)benzene] (17.59 g) were dissolved in propylene glycol methyl ether (70 mL). Methanesulfonic acid (1.96 g) was added and the solution was heated to 120° C. for 26 hours. The solution was then cooled to room temperature and precipitated into 1 L of water. The liquid was decanted off and the solution was redissolved in 50 mL tetrahydrofuran and precipitated into 500 mL water. The liquid was decanted off and the solution was redissolved in 50 mL tetrahydrofuran and precipitated into 500 mL heptanes. The liquid was decanted off and the polymer was dried under vacuum at 50° C. overnight, yielding 23.80 g of polymer A-3. Mw (by GPC): 2549 g/mol.

### Synthesis Example A4:

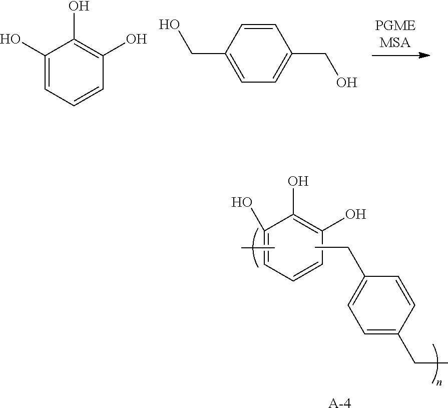

Pyrogallol (10.03 g) and 1,4-benzenedimethanol (10.21 g) were dissolved in propylene glycol methyl ether (40 mL). Methanesulfonic acid (0.76 g) was added and the solution was heated to 120° C. for 8 hours. The solution was then cooled to room temperature and precipitated into 1 L of a 70% water/30% methanol (v/v) mixture. The liquid was decanted off and the polymer was dried under vacuum at 50° C. overnight, yielding 11.89 g of polymer A-4. Mw (by GPC): 3754 g/mol.

### Synthesis Example A5:

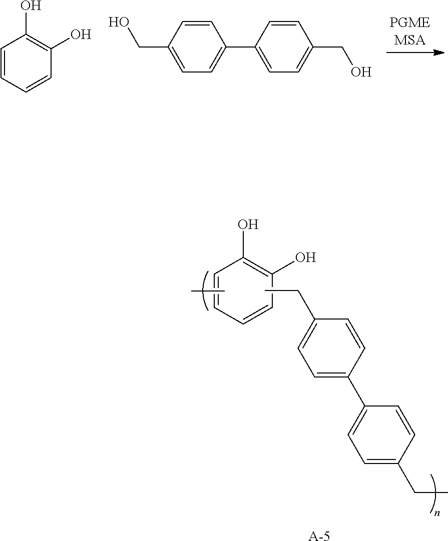

Catechol (5.01 g) and 4,4′-biphenyldimethanol (6.49 g) were dissolved in propylene glycol methyl ether (25 mL). Methanesulfonic acid (0.44 g) was added and the solution was heated to 120° C. for 8 hours. The solution was then cooled to room temperature and precipitated into 1 L of a 70% water/30% methanol (v/v) mixture. The liquid was decanted off and the polymer was redissolved in 50 mL tetrahydrofuran and precipitated into 1 L of a 50% water/50% methanol (v/v). The liquid was decanted off and the polymer was dried under vacuum at 50° C. overnight, yielding 6.44 g of polymer A-5. Mw (by GPC): 4365 g/mol.

Compound X-PHS is was obtained from a commercial source with a Mw (by GPC)=4,299 g/mol.) X-PHS=poly(hydroxystyrene).

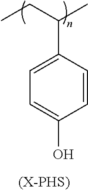

Compounds A1 to A6 are shown below for reference.

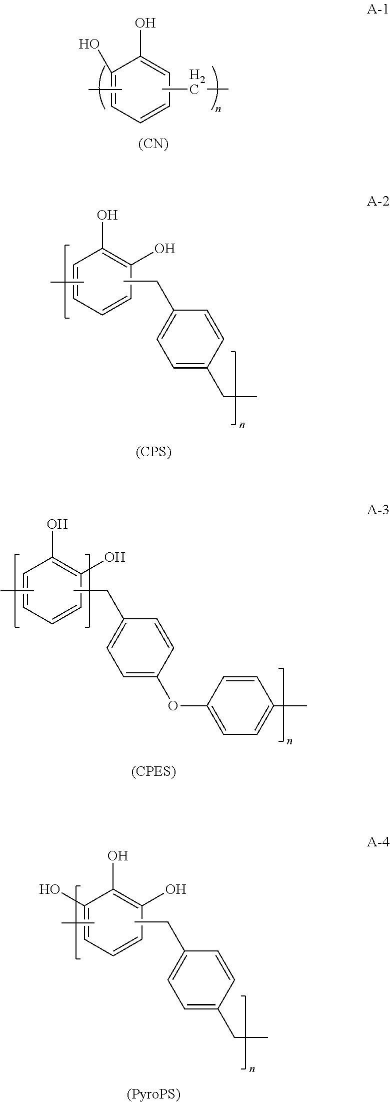

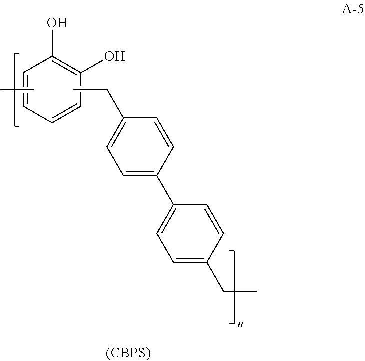

An exemplary list of B-epoxy compounds including a substituent group represented by Formula 2, and an exemplary list of comparative C-epoxy compounds are shown below. The B-epoxy compounds and C-epoxy compounds are prepared in accordance with procedures known in the art.

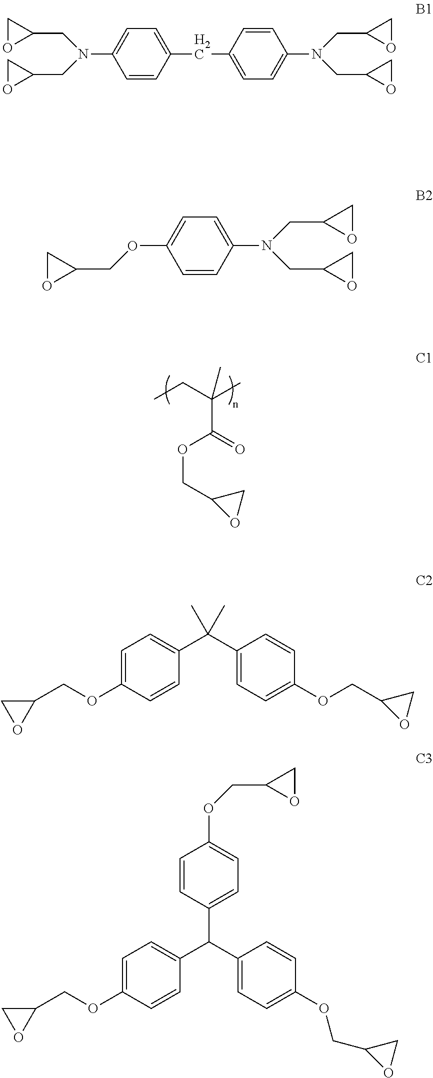

### Underlayer Composition Preparation

Underlayer composition formulations for Examples 1-7 & Comparative Examples 1-6 were prepared by mixing the components in Table 1 with the relative mass amounts provided.

TABLE 1
Composition Components

| | | Formula 2 | |
|---|---|---|---|
| Examples | Polymer | Compound | Solvent |
| Example 1 | A-1 CN (1.8) | B-1 4epoxy (2.4) | PGMEA (91.0)/GBL (4.8) |
| Example 2 | A-2 CPS (1.8) | B-1 4epoxy (2.4) | PGMEA (91.0)/GBL (4.8) |
| Example 3 | A-3 CPES (1.8) | B-1 4epoxy (2.4) | PGMEA (91.0)/GBL (4.8) |
| Example 4 | A-4 PyroPS (1.8) | B-1 4epoxy (2.4) | PGMEA (91.0)/GBL (4.8) |
| Example 5 | A-5 CBPS (1.8) | B-1 4epoxy (2.4) | PGMEA (91.0)/GBL (4.8) |
| Example 6 | A-1 CN (1.8) | B-2 3epoxy (2.4) | PGMEA (91.0)/GBL (4.8) |
| Comp. Example 1 | A-1 CN (2.9) | B-1 4epoxy (1.3) | PGMEA (91.0)/ GBL (4.8) |
| Comp. Example 2 | A-1 CN (1.8) | C-1 GMA (2.4) | PGMEA (91.0)/ GBL (4.8) |
| Comp. Example 3 | A-2 CPS (1.8) | C-1 GMA (2.4) | PGMEA (91.0)/GBL (4.8) |
| Comp. Example 4 | A-3 CPES (1.8) | C-1 GMA (2.4) | PGMEA (91.0)/GBL (4.8) |
| Comp. Example 5 | A-1 CN (1.8) | C-2 BADE (2.4) | PGMEA (91.0)/GBL (4.8) |
| Comp. Example 6 | A-1 CN (1.8) | C-3 TMTE (2.4) | PGMEA (91.0)/GBL (4.8) |
| Comp. Example 7 | A-2 CPS (1.8) | C-2 BADE (2.4) | PGMEA (91.0)/GBL (4.8) |
| Comp. Example 8 | A-2 CPS (1.8) | C-3 TMTE (2.4) | PGMEA (91.0)/GBL (4.8) |
| Comp. Example 9 | X-PHS (1.8) | B-1 4epoxy (2.4) | PGMEA (91.0)/GBL (4.8) |

CN = catechol novolac (M_{w} (GPC) = 2,290 g/mol);
X-PHS = poly(hydroxystyrene) (M_{w} (GPC) = 4,299 g/mol);
GMA = poly(glycidyl methacrylate (M_{w} (GPC) = 3,922 g/mol);
3epoxy = N,N-Diglycidyl-4-glycidyloxyaniline;
4epoxy = 4,4′-Methylenebis(N,N-diglycidylaniline);
BADE = Bisphenol A diglycidyl ether;
TMTE = Tris(4-hydroxyphenyl)methane triglycidyl ether;
PGMEA = propylene glycol methyl ether acetate;
GBL = Gamma butyrolactone;
Numerical values for components are relative mass amounts (or percent by weight).

### Solvent Strip Resistance Evaluation

Each composition in Table 1 was spin-coated onto a respective 200 mm silicon wafer on an ACT-8 Clean Track (Tokyo Electron Co.) at 1500 rpm, and then cured at 215° C. for 60 seconds to form a film. Initial film thickness was measured with a Therma-Wave OptiProbe™ metrology tool. PGMEA remover was then applied to each of the films for 90 seconds followed by a post-strip bake at 105° C. for 60 seconds. The thickness of each film was again measured to determine the amount of film thickness lost. The difference in film thickness before and after contact with the PGMEA remover is set forth in Table 2 as the percentage of film thickness remaining on the wafer (% Film Remaining). This value is indicative of the degree of crosslinking of the polymeric layer.

TABLE 2
Strip resistance of cured films

| | % film remaining |
|---|---|
| Examples | post strip |
| Example 1 | 100.0 |
| Example 2 | 99.7 |
| Example 3 | 99.8 |
| Example 4 | 99.9 |
| Example 5 | 99.9 |
| Example 6 | 99.9 |
| Comp. Example 1 | 99.8 |
| Comp. Example 2 | 100 |
| Comp. Example 3 | 100 |
| Comp. Example 4 | 100 |
| Comp. Example 5 | 7.9 |
| Comp. Example 6 | 70.7 |
| Comp. Example 7 | 5.2 |
| Comp. Example 8 | 43.2 |
| Comp. Example 9 | 100.0 |

As seen in Table 2, with the exception of the C1 epoxy of GMA, and the amino epoxides, for example, B1 or B2, the nonpolymeric epoxides are not fully strip resistant (see, comparative examples 5-8) which precludes their use as photoresist underlayers. All examples with N-epoxides become fully strip resistant. Although comparative examples 1 to 4 also exhibit favorable strip resistant, as shown below, these comparative compositions exhibit significantly less favorable planarizing ability. Moreover, comparative example 2 fails during SC1 resistance evaluation (see below).

### SC1 Resistance Evaluation

Each composition in Table 1 was spin-coated onto a 9 nm TiN coated defect template coupons (1×1 inch) on lab spin coater at 1500 rpm, and then cured at 215° C. for 60 seconds to form a film with 900 A thickness. These films were tested under 180 gram 50° C. SC1 bath with 1:1:5 (H₂O₂:NH₄OH:H₂O) and expected visually by eye after 5, 8 and 11 minutes

TABLE 3
Underlayer SC1 resistance evaluation

| | SC1 | SC1 | SC1 |
|---|---|---|---|
| | Resistance 5 | Resistance 8 | Resistance 11 |
| Examples | min. | min. | min. |
| Example 1 | A | A | B |
| Example 2 | A | A | A |
| Example 3 | A | A | A |
| Example 4 | A | B | — |
| Example 5 | A | A | A |
| Example 6 | A | B | C |
| Comp. Example 1 | A | C | |
| Comp. Example 2 | B | C | — |
| Comp. Example 3 | A | A | A |
| Comp. Example 4 | A | A | A |
| Comp. Example 5 | Not test due to lack of cross linking | | |
| Comp. Example 6 | | | |
| Comp. Example 7 | | | |
| Comp. Example 8 | | | |
| Comp. Example 9 | C | — | — |

A: Pristine film,
B: partial film degradation seen by visible eye,
C: fully delaminated film

As can be seen from Table 3, each of Examples 1 to 6 exhibit longer time until delamination occurs in comparison to comparative example 2. Comparative example 2 has partial film degradation after 5 minutes comparative example 9 is fully delaminated after 5 minutes, and comparative example 1 is fully delaminated after 8 minutes. In contrast, examples 4 and 6 demonstrates partial degradation after 8 minutes, example 1 demonstrates degradation after 11 minutes, and examples 2, 3, and 5 are all pristine films even after 11 minutes in the SC1 bath. Although comparative examples 3 and 4 exhibit good SC1 performance, the comparative examples have relatively poor planarization performance (see Table 4).

### PL Evaluation

The photoresist underlayer composition of the invention were evaluated to determine their planarization properties. A template with a SiO₂ film thickness of 100 nm, and various pitch and patterns with die size of 1 cm×1 cm. Each die started with a 100 nm isolated step pattern followed by a 2000 μm non-pattern open area, followed by various line/space patterns that covered 45 nm/90 nm to 2 μm /5 μm pitch trenches. The first step pattern was used to judge planarization performance. The template coupons were baked at 150° C. for 60 seconds as a dehydration bake prior to coating the coupons with the present compositions. Each photoresist underlayer composition was coated on a template coupon using a spin coater and a spin rate of 1500 rpm +/−200 rpm. The target film thickness was 100 nm after curing, and the composition dilution was adjusted accordingly to give approximately the target film thickness after curing. The films were cured by placing the wafer on a hot plate at 240° C. for 60 sec. Planarization quality of the films across a step was evaluated by KLA Tencor P-7 stylus profilometer.

In Table 4, planarization quality is defined as follows:

Isolated step area: A indicates a material flow transition width larger than 15 micrometers (μm), B indicates a material flow transition width between 10-15 μm, and C indicates a material flow transition width less than 10 μm.
Localized area: A indicates a change in height of less than 25 nanometers (nm), B indicates a change in height of between 25-35 nm, and C indicates a change in height of greater than 35 nm. Lower numbers indicate superior planarization performance, so A represents best planarization, followed by B, and C represents worst planarization performance. Accordingly, Examples 1, 2, 3, and 6 each demonstrate improved planarization in comparison to each of comparative examples 1 to 4 and 9.

TABLE 4
PL evaluation

| Examples | Isolated step area | Localized area |
|---|---|---|
| Example 1 | A | A |
| Example 2 | A | B |
| Example 3 | A | A |
| Example 6 | B | B |
| Comp. Example 1 | C | C |
| Comp. Example 2 | C | C |
| Comp. Example 3 | C | C |
| Comp. Example 4 | C | C |
| Comp. Example 5 | Could not be tested due to | |
| | lack of crosslinking | |
| Comp. Example 6 | Could not be tested due to | |
| | lack of crosslinking | |
| Comp. Example 7 | Could not be tested due to | |
| | lack of crosslinking | |
| Comp. Example 8 | Could not be tested due to | |
| | lack of crosslinking | |
| Comp. Example 9 | B | B |

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A method of forming a pattern, the method comprising:
applying a photoresist underlayer composition over a substrate to provide a photoresist underlayer;
forming a photoresist layer over the photoresist underlayer;
patterning the photoresist layer; and
transferring a pattern from the patterned photoresist layer to the photoresist underlayer;
wherein the photoresist underlayer composition comprises a polymer that includes a repeating unit represented by Formula 1, a compound including a substituent group represented by Formula 2; and a solvent; 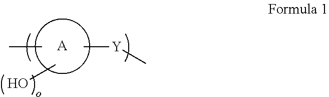
wherein in Formula 1
Ring A represents an aromatic group with one to four independently substituted or unsubstituted aromatic rings, wherein optionally, two or more of the aromatic rings are fused, one or more aromatic rings includes a fused optionally substituted cycloalkyl or an optionally substituted fused heterocycloalkyl, or a combination thereof,
Y is a divalent group comprising an optionally substituted C₁₋₄ alkylene, —O—, —S—, C(O)—, an optionally substituted arylene, or an optionally substituted heteroarylene, or a combination thereof, and
o is an integer from 2 to 8; 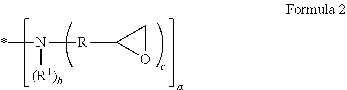
wherein, in Formula 2:
R is a substituted or unsubstituted C₁₋₄ alkylene, —CR^{A}R^{B}—Ar—CH₂—, or —Ar—CH₂—, where Ar is an optionally substituted arylene or heteroarylene with 4 to 10 ring carbons, and R^{A} and R^{B} are independently hydrogen, hydroxy, optionally substituted C₁₋₆ alkyl, optionally substituted C₁₋₆ alkoxy, or optionally substituted C₆₋₁₂ aryl;
R¹ is hydrogen, an optionally substituted C₁₋₄ alkyl, an optionally substituted C₆₋₁₂ aryl, an optionally substituted C₃₋₈ cycloalkyl, or glycidyl;
* is a connection point to a ring carbon of aromatic ring system Q, wherein the aromatic ring system Q is Ar¹ or Ar²-T-Ar³,
wherein Ar¹, Ar², and Ar³ comprise independently a substituted or unsubstituted aromatic group with 4 to 14 ring carbons, and
T is absent, —O—, —S—, —C(O)—, an optionally substituted C₁₋₄ alkylene, or —NR²—, wherein R² is hydrogen, an optionally substituted C₁₋₄ alkyl, or an optionally substituted C₆₋₁₂ aryl; and
a is 1 to 8, c is 1, 2, or 3, and b+c is 2 or 3.

2. The method of claim 1, wherein the Ring A of Formula 1 is represented by Formula 1A or Formula 1B 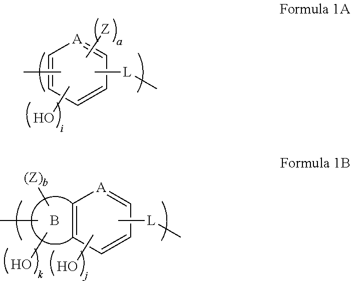
wherein, in Formula 1A and Formula 1B:
A is CR^{C} or N, wherein R^{C} is hydrogen, hydroxy, optionally substituted C₁₋₆ alkyl, optionally substituted C₁₋₆ alkoxy, or optionally substituted C₆₋₁₂ aryl;
ring B represents a fused aromatic group with one to four aromatic rings;
L is divalent group that comprises independently one to three optionally substituted C₁₋₄ alkylene, one to three —O—, optionally substituted arylene with one or two aromatic rings, or a combination thereof;
each Z is independently a substituent group where in Formula 1A, a is 0 or 1, and in Formula 1B, b is an integer from 0 to 10; i is 2 or 3; j is 0, 1, or 2; and k is an integer from 0 to 6, wherein j+k is 2 or more.

3. The method of claim 1, wherein Ar¹, Ar², and Ar³ are independently a substituted or unsubstituted phenyl, a substituted or unsubstituted naphthyl, a substituted or unsubstituted anthracenyl, a substituted or unsubstituted pyrenyl, a substituted or unsubstituted pyridinyl, a substituted or unsubstituted quinolinyl, a substituted or unsubstituted biphenylene, a substituted or unsubstituted triphenylene, a substituted or unsubstituted fluorenyl, or a substituted or unsubstituted carbazoyl, and each of which is optionally substituted with glycidyl.

4. The method of claim 1, wherein
Q is Ar¹, and Ar¹ is phenyl, R is CH₂, a is 1 or 2, and c is 2;
Q is Ar¹, and Ar¹ is phenyl substituted with glycidyl, R is CH₂, a is 1 or 2, and c is 2;
Q is Ar²-T-Ar³, and Ar² and Ar³ are phenyl, and T is absent, —O—, —C(O)—, or —CR^{B}R^{C}—, and for each of Ar² and Ar³, a is 1 or 2, and c is 2; or
Q is Ar²-T-Ar³, and Ar² or Ar³ is a phenyl substituted with glycidyl, and T is absent, —O—, —C(O)—, or —CR^{D}R^{E}—, and for each of Ar² and Ar³, a is 1 or 2, and c is 2;
wherein R^{D} and R^{E} are independently hydrogen, an optionally substituted C₁₋₄ alkyl, or an optionally substituted phenyl.

5. The method of claim 1, wherein the polymer including a repeating unit represented by Formula 1 comprises a repeating unit represented by Formula 3A or Formula 3B; 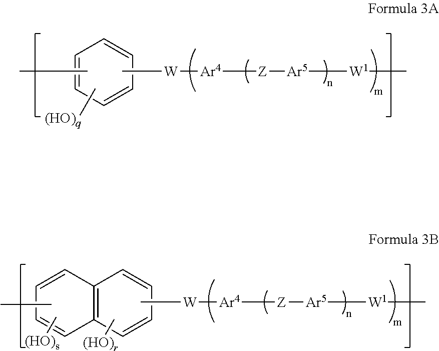
wherein, in Formulae 3A and 3B:
W and W¹ are independently an optionally substituted C₁₋₄ alkylene, —O—, or a combination thereof;
Ar⁴ and Ar⁵ are independently an optionally substituted C₆₋₁₄ arylene, or an optionally substituted C₃₋₁₄ heteroarylene;
Z is absent, O, —S—, —C(O)—, an optionally substituted C₁₋₄ alkylene;
m is 0, 1, or 2, n is 0 or 1, and m+n is 1, 2, or 3; and
q is 2 or 3; and
r and s are independently 0, 1, or 2, wherein r+s is 2 or more.

6. The method of claim 5, wherein
if n is 0, and m is 1 or 2, then W and W¹ are independently —CR^{F}R^{G}—; and
Ar⁴ is a substituted or unsubstituted phenyl, a substituted or unsubstituted pyridinyl, a substituted or unsubstituted biphenyl, or a substituted or unsubstituted naphthyl, wherein R^{F} and R^{G} are independently hydrogen, hydroxy, an optionally substituted C₁₋₁₈ alkyl, an optionally substituted C₁₋₁₈ alkoxy, Ar⁶, —CH₂Ar⁶, —OAr⁶, —Ar⁶R⁴, where Ar6 is an optionally substituted C₆₋₁₈ aryl, and R⁴ is an optionally substituted C₁₋₁₈ alkyl or an optionally substituted C₁₋₁₈ alkoxy.

7. The method of claim 1, wherein the compound comprising a substituent group represented by Formula 2 includes at least one of the following compounds 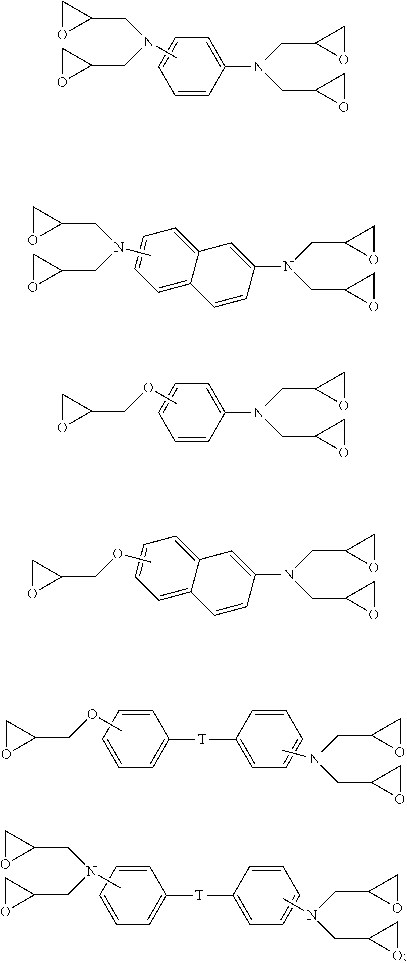
wherein T is as defined in claim 1.

8. The method of claim 1, wherein a weight ratio of the polymer including a repeating unit with two or more hydroxy groups of Formula 1 to the material including an aromatic substituent group represented by Formula 2 is in a range of 4:1 to 1:20.

9. The method of claim 1, wherein photoresist underlayer composition further comprises an additive represented by a compound of Formula 5, a compound of Formula 6, or a combination thereof 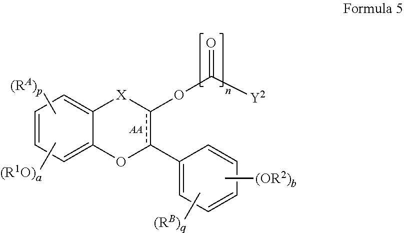
wherein in Formula 5,
AA is a single bond or a double bond, and it is to be understood that “AA” refers to the moiety having the structure represented by [symbol] in Formula (5);
X is a single bond, —C(O)—, unsubstituted C₁ alkylene, or hydroxy-substituted C₁ alkylene;
R¹ and R² are each independently hydrogen, substituted or unsubstituted C₁₋₂₂ alkyl, substituted or unsubstituted C₃₋₁₄ cycloalkyl, —C(O)OR^{5a}, or glycidyl, wherein R^{5a} is hydrogen, substituted or unsubstituted C₁₋₂₂ alkyl, substituted or unsubstituted C₁₋₂₂ heteroalkyl, substituted or unsubstituted C₃₋₁₄ cycloalkyl, substituted or unsubstituted C₂₋₁₄ heterocycloalkyl, substituted or unsubstituted C₂₋₂₂ alkenyl, substituted or unsubstituted C₆₋₂₄ aryl, substituted or unsubstituted C₇₋₂₄ arylalkyl, substituted or unsubstituted C₇₋₂₄ alkylaryl, or substituted or unsubstituted C₃₋₂₄ heteroaryl;
Y² is hydrogen, substituted or unsubstituted C₆₋₂₄ aryl, or substituted or unsubstituted C₃₋₂₄ heteroaryl; and
each R^{A} and each R^{B} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl; and
a is 2, 3, or 4; p is 0, 1, or 2; q is 0, 1, 2, or 3; m is an integer from 1 to 6; and n is 0 or 1; 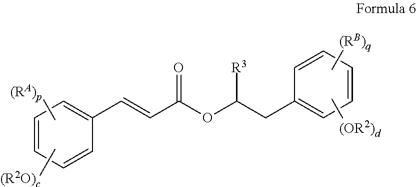
wherein in Formula 6, R², R^{B}, p, and q, is the same as R^{A}, as defined for Formula 5, and R³ is hydrogen, a carboxylic acid group or a derivative thereof, and
c and d are each independently an integer from 2 to 5.

10. The method of claim 1, wherein photoresist underlayer composition is free of non-polymeric polyphenol compounds and thermal base generators.

11. A composition comprising:
a polymer that includes a repeating unit represented by Formula 1; a compound including a substituent group represented by Formula 2; and a solvent; 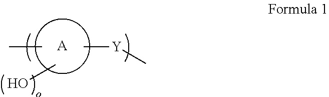
wherein in Formula 1
Ring A represents an aromatic ring system with one to four substituted or unsubstituted aromatic rings, wherein optionally, two or more of the aromatic rings are fused, one or more aromatic rings includes a fused optionally substituted cycloalkyl ring or an optionally substituted fused heterocycloalkyl, or a combination thereof,
Y is a divalent linker comprising an optionally substituted C₁₋₄ alkylene, an optionally substituted aromatic group, or a combination thereof, and
o is an integer from 2 to 8; 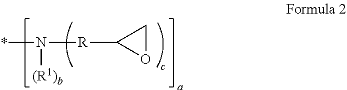
wherein, in Formula 2:
R is a substituted or unsubstituted C₁₋₄ alkylene, —CR^{A}R^{B}—Ar—CH₂—, or —Ar—CH₂—, where Ar is an optionally substituted arylene or heteroarylene with 4 to 10 ring carbons, and R^{A} and R^{B} are independently hydrogen, hydroxy, optionally substituted C₁₋₆ alkyl, optionally substituted C₁₋₆ alkoxy, or optionally substituted C₆₋₁₂ aryl;
R¹ is hydrogen, an optionally substituted C₁₋₄ alkyl, an optionally substituted C₆₋₁₂ aryl, an optionally substituted C₃₋₈ cycloalkyl, or glycidyl;
* is a connection point to a ring carbon of aromatic ring system Q, wherein the aromatic ring system Q is Ar¹ or Ar²-T-Ar³,
wherein Ar¹, Ar², and Ar³ comprise independently a substituted or unsubstituted aromatic group with 4 to 14 ring carbons, and
T is absent, —O—, —S—, —C(O)—, an optionally substituted C₁₋₄ alkylene, or —NR²—, wherein R² is hydrogen, an optionally substituted C₁₋₄ alkyl, or an optionally substituted C₆₋₁₂ aryl; and
a is 1 to 8, c is 1, 2, or 3, and b+c is 2 or 3;
wherein the composition is a photoresist underlayer composition.

12. The composition of claim 11, wherein the polymer including a repeating unit represented by Formula 1 comprises a repeating unit represented by Formula 3A or Formula 3B; 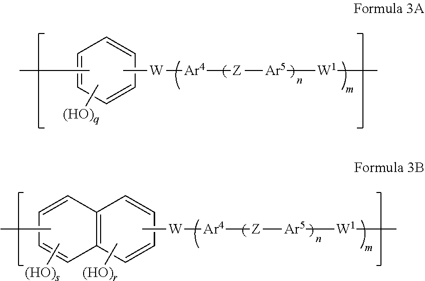
wherein, in Formulae 3A and 3B:
W and W¹ are independently an optionally substituted C₁₋₄ alkylene, —O—, or a combination thereof;
Ar⁴ and Ar⁵ are independently an optionally substituted C₆₋₁₄ arylene, or an optionally substituted C₃₋₁₄ heteroarylene;
Z is absent, O, —S—, —C(O)—, an optionally substituted C₁₋₄ alkylene;
m is 0, 1, or 2, n is 0 or 1, and m+n is 1, 2, or 3; and
q is 2 or 3; and
r and s are independently 0, 1, or 2, wherein r+s is 2 or more.

13. The composition of claim 10, wherein the photoresist composition is free of non-polymeric polyphenol compounds and thermal base generators.
